(19) United States
(12) Patent Application Publication
(10) Pub. No.: US 2026/0032914 A1
(43) Pub. Date: Jan. 29, 2026

(54) SEMICONDUCTOR DEVICE, AND SEMICONDUCTOR CHIP AND ELECTRONIC SYSTEM INCLUDING THE SAME

(71) Applicant: Samsung Electronics Co., Ltd., Suwon-si (KR)

(72) Inventors: Eun-Young LEE, Suwon-si (KR); Woosung LEE, Suwon-si (KR)

(73) Assignee: Samsung Electronics Co., Ltd., Suwon-si (KR)

(21) Appl. No.: 19/014,966

(22) Filed: Jan. 9, 2025

(30) Foreign Application Priority Data
Jul. 29, 2024 (KR) 10-2024-0100246

(51) Int. Cl. H10B 43/40; H10B 41/41

(52) U.S. Cl. CPC H10B 43/40; H10B 41/41

(57) ABSTRACT

A semiconductor chip according to some example embodiments includes a substrate, a plurality of transistors on the substrate, each of the plurality of transistors including a gate structure and a spacer on a side surface of the gate structure, the gate structure including a gate insulation layer, a gate electrode, and a capping layer, at least a portion of the capping layer is on the gate electrode, and the capping layer includes an insulating material, and a cover layer includes a material different from a material of the spacer, and the cover layer covers the gate structure and the spacer. The capping layer includes a first surface opposite to the gate electrode, and a second surface adjacent to the gate electrode.

### CROSS-REFERENCE TO RELATED APPLICATION

This application claims priority to and the benefit of Korean Patent Application No. 10-2024-0100246 filed in the Korean Intellectual Property Office on Jul. 29, 2024, the entire contents of which are incorporated herein by reference.

### BACKGROUND

Some example embodiments relate to a semiconductor device, and a semiconductor chip and an electronic system including the same.

Semiconductor devices and semiconductor chips may have a small size and perform various functions, and thus are widely used in various electronic industries. As advancements are made in electronic industries, research on improving the performance of semiconductor devices and/or semiconductor chips has continued to progress. For example, the performance of semiconductor devices and/or the semiconductor chips may be improved by enhancing reliability and/or performance of a plurality of circuit elements included in the semiconductor devices and/or the semiconductor chips.

### SUMMARY

Some example embodiments of the present disclosure provide a semiconductor device, having enhanced performance and/or reliability, and a semiconductor chip and an electronic system including the same.

A semiconductor chip according to some example embodiments includes a substrate, a plurality of transistors on the substrate, each of the plurality of transistors including a gate structure and a spacer on a side surface of the gate structure, the gate structure including a gate insulation layer, a gate electrode, and a capping layer, at least a portion of the capping layer is on the gate electrode, and the capping layer includes an insulating material, and a cover layer includes a material different from a material of the spacer, and the cover layer covers the gate structure and the spacer. The capping layer includes a first surface opposite to the gate electrode, and a second surface adjacent to the gate electrode, and an upper end of the spacer adjacent to the side surface of the gate structure is between the first surface of the capping layer and the second surface of the capping layer in a vertical direction, the vertical direction being a direction perpendicular to an upper surface of the substrate.

A semiconductor device according to some example embodiments includes a gate structure on a substrate, the gate structure including a gate insulation layer, a gate electrode, and a capping layer, at least a portion of the capping layer is on the gate electrode, and the capping layer includes an insulating material, a spacer on a side surface of the gate structure, and a cover layer that includes a material different from a material of the spacer, and the cover layer covers the gate structure and the spacer. The capping layer includes a first surface that is opposite to the gate electrode, and a second surface that is adjacent to the gate electrode. An upper end of the spacer adjacent to the side surface of the gate structure is between the first surface of the capping layer and the second surface of the capping layer in a vertical direction, the vertical direction being a direction perpendicular to an upper surface of the substrate.

An electronic system according to some example embodiments includes a main substrate, a semiconductor chip on the main substrate, and a controller electrically connected the semiconductor chip on the main substrate. The semiconductor chip includes a substrate, a plurality of transistors on the substrate, each of the plurality of transistors including a gate structure and a spacer on a side surface of the gate structure, the gate structure including a gate insulation layer, a gate electrode, and a capping layer, at least a portion of the capping layer is on the gate electrode, and the capping layer includes an insulating material, and a cover layer including a material different from a material of the spacer and covers the gate structure and the spacer. The capping layer includes a first surface that is opposite to the gate electrode, and a second surface that is adjacent to the gate electrode. An upper end of the spacer adjacent to the side surface of the gate structure is between the first surface of the capping layer and the second surface of the capping layer in a vertical direction, the vertical direction being a direction perpendicular to an upper surface of the substrate.

According to some example embodiments, an upper end of a spacer may be spaced apart from a first surface of a capping layer by a first separation distance on a side surface of a gate structure, and a side portion of the capping layer in which a cover layer is on an upper portion of the spacer may be included. Accordingly, a height of the cover layer on the upper portion of the spacer may sufficiently protect the underlying spacer. Thereby, damage and/or property changes of a transistor which may be induced by subsequent processes may be reduced and/or minimized, and performance and/or reliability of the transistor may be enhanced. Particularly, in a circuit region or a semiconductor chip that includes a plurality of transistors having different heights.

### BRIEF DESCRIPTION OF THE DRAWINGS

FIG. 1 is a partial cross-sectional view that schematically illustrates a semiconductor chip according to some example embodiments.

FIG. 2 is an enlarged cross-sectional view that illustrates an example of a channel structure included in the semiconductor chip illustrated in FIG. 1.

FIG. 3 is an enlarged cross-sectional view of a portion A in FIG. 1.

FIG. 4 a cross-sectional view that illustrates one of a plurality of transistors illustrated in FIG. 3.

FIG. 5 to FIG. 10 are cross-sectional views that illustrate a manufacturing method of a semiconductor chip according to some example embodiments.

FIG. 11 to FIG. 13 are cross-sectional views that illustrate a manufacturing method of a semiconductor chip according to some example embodiments.

FIG. 14 is a partial cross-sectional view that schematically illustrates a semiconductor chip according to some example embodiments.

FIG. 15 schematically illustrates an electronic system that includes a semiconductor device or a semiconductor chip according to some example embodiments.

FIG. 16 is a perspective view that schematically illustrates an electronic system including a semiconductor device or a semiconductor chip according to some example embodiments.

FIG. 17 is a cross-sectional view that schematically illustrates a semiconductor package according to some example embodiments.

FIG. 18 is a cross-sectional view that schematically illustrates a semiconductor package according to some example embodiments.

### DETAILED DESCRIPTION

Some example embodiments of the present disclosure will be described more fully hereinafter with reference to the accompanying drawings for those skilled in the art to which the present disclosure pertains to easily practice the present disclosure. The present disclosure may be implemented in various different forms and is not limited to the example embodiments provided herein.

A portion unrelated to the description is omitted in order to clearly describe the present disclosure, and the same or similar components are denoted by the same reference numeral throughout the present specification.

Further, since a size and/or a thickness of a portion, a region, a member, a unit, a layer, a film, a substrate, or so on illustrated in the accompanying drawings may be arbitrarily illustrated for better understanding and convenience of explanation, the present disclosure is not limited to the illustrated size and/or thickness. In the drawings, thicknesses of portions, regions, members, units, layers, films, etc. may be enlarged or exaggerated for convenience of explanation and/or simple illustration

It will be understood that when a component such as a portion, a region, a member, a unit, a layer, a film, a substrate, or so on is referred to as being “on” another component, it may be directly on another component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-section taken along a vertical direction is viewed from a side.

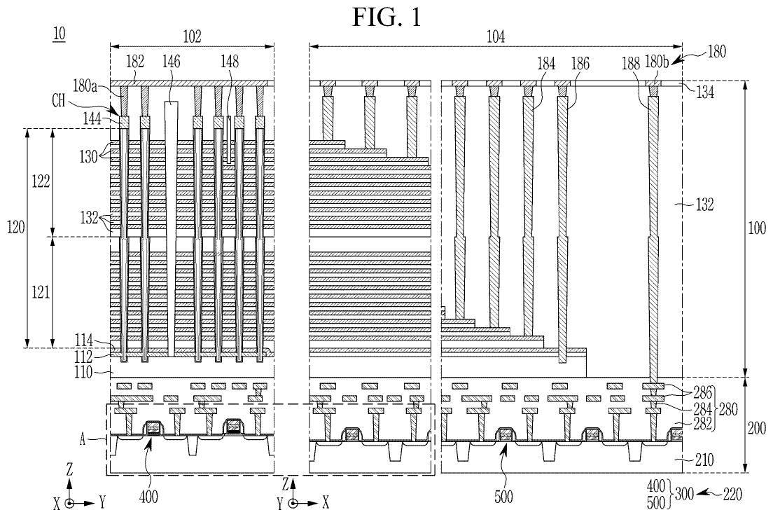

Hereinafter, with reference to FIG. 1 to FIG. 13, a semiconductor chip according to some example embodiments and manufacturing methods of the semiconductor chip will be described in detail.

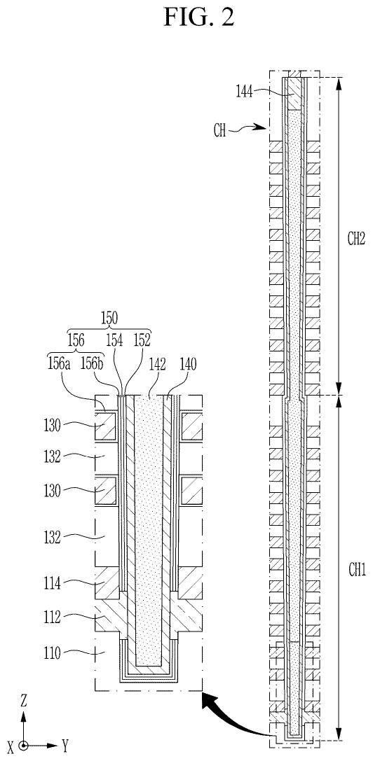

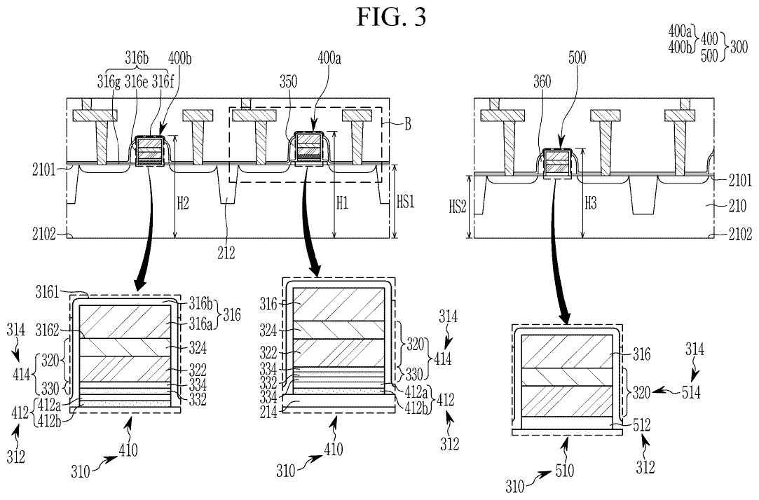

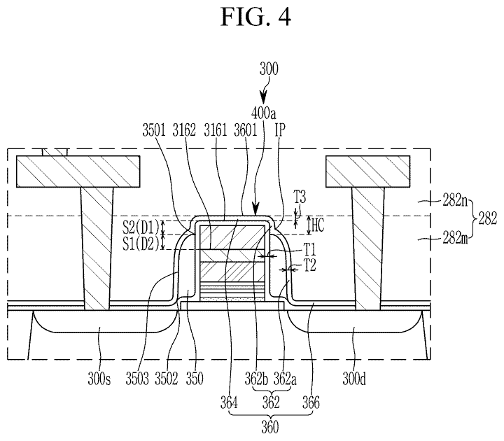

FIG. 1 is a partial cross-sectional view that schematically illustrates a semiconductor chip 10 according to some example embodiments. FIG. 2 is an enlarged cross-sectional view that illustrates an example of a channel structure CH included in the semiconductor chip 10 illustrated in FIG. 1. Coordinates of FIG. 1 relate to a cell region 100. FIG. 1 illustrates a cross-sectional view of a circuit region 200 where a gate structure 310 (refer to FIG. 3), a spacer 350 (refer to FIG. 3), and source and drain regions 300s and 300d (refer to FIG. 4) are positioned together regardless of the coordinates of FIG. 1.

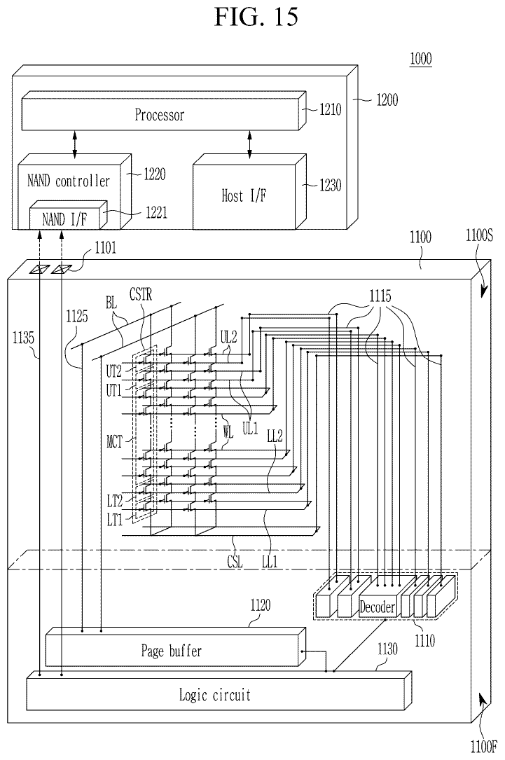

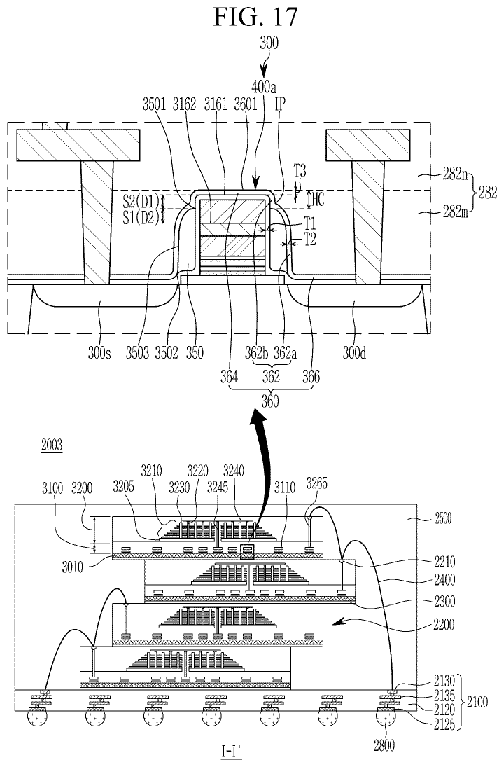

Referring to FIG. 1 and FIG. 2, a semiconductor chip 10 according to some example embodiments may include a cell region 100 that includes a memory cell structure and a circuit region 200 that includes a peripheral circuit structure controlling an operation of the memory cell structure. The semiconductor chip 10 may be referred to as a semiconductor device, a semiconductor die, or a semiconductor apparatus. For example, the circuit region 200 and the cell region 100 may correspond to a first structure 1100F and a second structure 1100S of a semiconductor device 1100 included in an electronic system 1000 illustrated in FIG. 15, respectively. For example, the circuit region 200 and the cell region 100 may be portions including a first structure 3100 and a second structure 3200 of a semiconductor chip 2200 illustrated in FIG. 17, respectively.

The circuit region 200 may include the peripheral circuit structure on a first substrate 210, and the cell region 100 may include a gate stacking structure 120 and a channel structure CH as the memory cell structure on a second substrate 110. The circuit region 200 may include a first wiring portion 280, and the cell region 100 may include a second wiring portion 180 electrically connected to the memory cell structure.

In some example embodiments, the cell region 100 may be disposed on the circuit region 200. Accordingly, an area corresponding to the circuit region 200 may be substantially the same as the cell region 100. Therefore, an area of the semiconductor chip 10 may be reduced. However, example embodiments are not limited thereto, and the circuit region 200 may be disposed next to the cell region 100. Various other modifications are possible.

The cell region 100 may include a cell array region 102 and a connection region 104. The gate stacking structure 120 and the channel structure CH may be disposed on the second substrate 110 in the cell array region 102. A structure that connects the gate stacking structure 120 and/or the channel structure CH in the cell array region 102 to the circuit region 200 or an external circuit may be in the cell array region 102 and/or the connection region 104.

In some example embodiments, the second substrate 110 may include a semiconductor layer including a semiconductor material. For example, the second substrate 110 may be a semiconductor substrate including or formed of a semiconductor material or may be a semiconductor substrate in which a semiconductor layer is disposed on a base substrate. For example, the second substrate 110 may include or be formed of silicon, germanium, silicon-germanium, silicon on insulator (SOI), germanium on insulator (GOI), or so on. However, example embodiments are not limited thereto. A p-type dopant or an n-type dopant may be doped to the semiconductor layer included in the second substrate 110. For example, the p-type dopant may include as boron (B), gallium (Ga), or so on, and the n-type dopant may include phosphorus (P), arsenic (As), or so on. However, the example embodiments are not limited to a material of the second substrate 110, a conductive type of the dopant doped to the semiconductor layer, or so on.

In the cell array region 102, the gate stacking structure 120 and the channel structure CH may be positioned. The gate stacking structure 120 may include cell insulation layers 132 and gate electrode layers 130 alternately stacked on a first surface (e.g., a front surface or an upper surface) of the second substrate 110. The channel structure CH may extend in a direction crossing the second substrate 110 (a Z-axis direction in the drawings) while passing through or penetrating the gate stacking structure 120.

In some example embodiments, horizontal conductive layers 112 and 114 may be provided between the second substrate 110 and the gate stacking structure 120 in the cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 sequentially on the second substrate 110. The first horizontal conductive layer 112 may act as a partial portion of a common source line of the semiconductor chip 10. For example, the first horizontal conductive layer 112 may act as the common source line together with the second substrate 110.

The first and the second horizontal conductive layers 112 and 114 may include or be formed of a semiconductor material (e.g., polycrystalline silicon). For example, the first horizontal conductive layer 112 may include or be formed of a polycrystalline silicon layer including a dopant. However, the example embodiments are not limited thereto. The second horizontal conductive layer 114 may include or be formed of a material (e.g., an insulating material) different from a material of the first horizontal conductive layer 112, or the second horizontal conductive layer 114 might not be provided.

The gate stacking structure 120 may be disposed on the second substrate 110 (e.g., on the first and second horizontal conductive layers 112 and 114 on the second substrate 110). The gate stacking structure 120 may include cell insulation layers 132 and gate electrode layers 130 alternately stacked to each other.

The gate electrode layer 130 may include any of various conductive materials. For example, the gate electrode layer 130 may include or be formed of a metal material (e.g., tungsten (W), copper (Cu), aluminum (Al), or so on), polycrystalline silicon, metal nitride (e.g., titanium nitride (TiN), tantalum nitride (TaN), or so on), or a combination thereof. However, example embodiments are not limited thereto. As illustrated in an enlarged view of FIG. 2, a partial portion of a blocking layer 156 (e.g., a first blocking layer 156a) including or being formed of an insulating material may be disposed outside the gate electrode layer 130. The cell insulation layer 132 may include any of various insulating materials. For example, the cell insulation layer 132 may include silicon oxide, silicon nitride, silicon oxynitride, a low dielectric constant material having a lower dielectric constant than silicon oxide, or a combination thereof. However, example embodiments are not limited thereto.

In some example embodiments, the channel structure CH may be provided. The channel structure CH may extend in a direction crossing the second substrate 110 (e.g., a vertical direction perpendicular to the second substrate 110 or the Z-axis direction in the drawings) to pass through the gate stacking structure 120.

The channel structure CH may include a channel layer 140, and a gate dielectric layer 150 on the channel layer 140 between the gate electrode layer 130 and the channel layer 140. The channel structure CH may further include a core insulation layer 142 at an inside of the channel layer 140. In some example embodiments, the core insulation layer 142 might not be provided. The channel structure CH may further include a channel pad 144 on the channel layer 140 and/or the gate dielectric layer 150. The gate dielectric layer 150 between the gate electrode layer 130 and the channel layer 140 may include a tunneling layer 152, a charge storage layer 154, and a blocking layer 156 sequentially on the channel layer 140.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape, a zigzag shape, or so on in a plan view. However, example embodiments are not limited thereto. The channel structure CH may have a pillar shape. For example, the channel structure CH may have an inclined side surface such that a width of the channel structure CH decreases toward the second substrate 110 due to an aspect ratio. However, the example embodiments are not limited thereto, and an arrangement, a structure, a shape, or so on of the channel structure CH may be variously modified.

The channel layer 140 may include a semiconductor material (e.g., polycrystalline silicon). The core insulation layer 142 may include any of various insulating materials. For example, the core insulation layer 142 may include or be formed of silicon oxide, silicon nitride, silicon oxynitride, or a combination thereof. However, example embodiments are not limited thereto.

The tunneling layer 152 may include or be formed of an insulating material that is capable of tunneling a charge (e.g., silicon oxide, silicon oxynitride, or so on). However, example embodiments are not limited thereto. The charge storage layer 154 may be used as a data storage region, and the charge storage layer 154 may include or be formed of polycrystalline silicon, silicon nitride, or so on. However, example embodiments are not limited thereto. The blocking layer 156 may include or be formed of an insulating material that is capable of limiting and/or preventing an undesirable flow of charge into the gate electrode layer 130. The blocking layer 156 may include or be formed of, for example, silicon oxide, silicon nitride, silicon oxynitride, a high dielectric constant material having a higher dielectric constant than silicon oxide, or a combination thereof. However, example embodiments are not limited thereto. In some example embodiments, the blocking layer 156 may include a first blocking layer 156a including a portion horizontally extending on the gate electrode layer 130, and a second blocking layer 156b vertically extending between the first blocking layer 156a and the charge storage layer 154.

However, a material, a stacking structure, or so on of the channel layer 140, the core insulation layer 142, or the gate dielectric layer 150 may be variously modified, and the example embodiments are not limited thereto.

The channel pad 144 may cover an upper surface of the core insulation layer 142 and be disposed to be electrically connected to the channel layer 140. The channel pad 144 may include or be formed of a conductive material (e.g., polycrystalline silicon doped with a dopant), but the example embodiments are not limited thereto.

In some example embodiments, the gate stacking structure 120 may include a plurality of gate stacking structures 120a and 120b sequentially stacked. Thereby, a number of stacked gate electrode layers 130 may be increased, and a number of memory cells may be increased with a stable structure. In FIG. 1, it is illustrated as an example that the gate stacking structure 120 includes first and second gate stacking structures 121 and 122. In some example embodiments, the gate stacking structure 120 may include one gate stacking structure or three or more gate stacking structures.

When the plurality of gate stacking structures 121 and 122 are provided as in the above, the channel structure CH may include a plurality of channel structures CH1 and CH2 that respectively pass through the plurality of gate stacking structures 121 and 122. The plurality of channel structures CH1 and CH2 may have a shape in which the plurality of channel structures CH1 and CH2 are connected to each other. In a cross-sectional view, each of the plurality of channel structures CH1 and CH2 may have an inclined side surface such that a width of each of the plurality of channel structures CH1 and CH2 decreases toward the second substrate 110 according to an aspect ratio. A bent portion due to a difference in widths of the plurality of channel structures CH1 and CH2 may be provided at a boundary portion of the plurality of channel structures CH1 and CH2. In some example embodiments, the plurality of channel structures CH1 and CH2 may have an inclined side surface that is continuously extended without the bent portion. In FIG. 2, it is illustrated as an example that the gate dielectric layer 150, the channel layer 140, and the core insulation layer 142 of the plurality of channel structures CH1 and CH2 continuously extend to have an integral structure. In some example embodiments, gate dielectric layers 150, channel layers 140, and core insulation layers 142 of the plurality of channel structures CH1 and CH2 may be separately formed and be electrically connected to each other. In some example embodiments, a separate channel pad may be additionally at the boundary portion of the plurality of channel structures CH1 and CH2. As such, the example embodiments are not limited to a shape of a plurality of channel structures CH1 and CH2.

In some example embodiments, the gate stacking structure 120 may be divided into a plurality of portions in a plan view by a separation structure 146 extending in a direction crossing the second substrate 110 (e.g., in the vertical direction or the Z-axis direction in the drawings) to pass through the gate stacking structure 120. An upper separation region 148 may be at a portion adjacent to an upper portion of the gate stacking structure 120. In a plan view, a plurality of separation structures 146 and/or a plurality of upper separation regions 148 may extend in an extension direction (an X-axis direction in the drawings) of the gate electrode layer 130 and be spaced apart from each other at a desired (and/or alternatively predetermined) interval in a crossing direction or a transverse direction (a Y-axis direction in the drawings) of the gate electrode layer 130.

The separation structure 146 and/or the upper separation region 148 may be filled with any of various insulating materials. For example, the separation structure 146 or the upper separation region 148 may include an insulating material such as silicon oxide, silicon nitride, or silicon oxynitride. However, the example embodiments are not limited thereto, and a structure, a shape, a material, or so on of the separation structure 146 or the upper separation region 148 may be variously modified.

The connection region 104 and the second wiring portion 180 may be provided to connect the gate stacking structure 120 and the channel structure CH in the cell array region 102 to the circuit region 200 or an external circuit. The connection region 104 may be at a periphery of the cell array region 102 and a partial portion of the second wiring portion 180 may be in the connection region 104.

The second wiring portion 180 may include a member electrically connecting the gate electrode layer 130, the channel structure CH, the horizontal conductive layers 112 and 114, and/or the second substrate 110 to the circuit region 200 or the external circuit. For example, the second wiring portion 180 may include a bit line 182, a gate contact portion 184, a source contact portion 186, a through plug 188, a contact via 180a, and a connection wiring 180b. The contact via 180a may be connected to each of the bit line 182, the gate contact portion 184, the source contact portion 186, and/or the through plug 188. The connection wiring 180b may be electrically connected to the bit line 182, the gate contact portion 184, the source contact portion 186, the through plug 188, and/or the contact via 180a.

The bit line 182 may extend in the crossing direction or the transverse direction (the Y-axis direction in the drawings) that crosses or is transverse to the extension direction (the X-axis direction in the drawings) of the gate electrode layer 130. The bit line 182 may be electrically connected to the channel structure CH (e.g., the channel pad 144) through the contact via 180a (e.g., a bit line contact via) that passes through or penetrates the cell insulation layer 132.

In the connection region 104, a plurality of gate contact portions 184 may pass through the cell insulation layer 132 to be electrically connected to the plurality of gate electrode layers 130, respectively, extended to the connection region 104. In the drawing, it is illustrated as an example that the plurality of gate electrode layers 130 may have a stair shape in one direction or a plurality of directions in the connection region 104, but the example embodiments are not limited thereto. In the connection region 104, the source contact portion 186 may pass through the cell insulation layer 132 to be electrically connected to the horizontal conductive layers 112 and 114 and/or the second substrate 110. The through plug 188 may pass through or penetrate the gate stacking structure 120 or may be disposed at an outside of the gate stacking structure 120 to be electrically connected to the first wiring portion 280 of the circuit region 200.

In FIG. 1, it is illustrated as an example that each of the gate contact portion 184, the source contact portion 186, and/or the through plug 188 has an inclined side surface such that a width of each of the gate contact portion 184, the source contact portion 186, and/or the through plug 188 decreases toward the second substrate 110 due to an aspect ratio and a bent portion is provided at the boundary portion of the plurality of gate stacking structures 121 and 122 in a cross-sectional view. However, the example embodiments are not limited thereto. In some example embodiments, the gate contact portion 184, the source contact portion 186, and/or the through plug 188 might not include the bent portion at the boundary portion of the plurality of gate stacking structures 121 and 122. Various other modifications are possible.

In FIG. 1, it is illustrated as an example that the connection wiring 180b is a single layer on the same plane as the bit line 182 and a second insulation layer 134 is at a portion other than the second wiring portion 180. However, this is brief illustration for convenience. For an electrical connection with the bit line 182, the gate contact portion 184, the source contact portion 186, and/or the through plug 188, the connection wiring 180b may include a plurality of wiring layers and may further include a contact via.

By the second wiring portion 180 and the first wiring portion 280, the bit line 182 connected to the channel structure CH, the gate electrode layer 130, the horizontal conductive layers 112 and 114, and/or the second substrate 110 may be electrically connected to a circuit element 220 of the circuit region 200.

The circuit region 200 may include the first substrate 210, and a circuit element 220 and the first wiring portion 280 on the first substrate 210.

The first substrate 210 may be a semiconductor substrate including a semiconductor material. For example, the first substrate 210 may be a semiconductor substrate including or formed of a semiconductor material or may be a semiconductor substrate in which a semiconductor layer is disposed on a base substrate. For example, the first substrate 210 may include or be formed of silicon, epitaxial silicon, germanium, or silicon-germanium that has a single-crystalline or polycrystalline structure, silicon on insulator, germanium on insulator, or so on. However, example embodiments are not limited thereto.

The circuit element 220 on the first substrate 210 may include any of various circuit elements that control an operation of the memory cell structure in the cell region 100. For example, the circuit element 220 may include the peripheral circuit structure such as a decoder circuit 1110 (refer to FIG. 15), a page buffer 1120 (refer to FIG. 15), a logic circuit 1130 (refer to FIG. 15), or so on.

The circuit element 220 may include, for example, a plurality of transistors 300, but the example embodiments are not limited thereto. In some example embodiments, the plurality of transistors 300 may include a first transistor 400 and a second transistor 500. This will be described later in more detail. The circuit element 220 may include not only an active element such as the transistor 300 or so on but also a passive element such as a capacitor, a resistor, an inductor, or so on. The transistor 300 may be referred to as a semiconductor device.

The first wiring portion 280 on the first substrate 210 may be electrically connected to the circuit element 220. In some example embodiments, the first wiring portion 280 may include a plurality of wiring layers 286 that are spaced apart from each other while interposing a first insulation layer 282 therebetween and are electrically connected by a contact via 284 to form a desired path. The wiring layer 286 or the contact via 284 may include any of various conductive materials, and the first insulation layer 282 may include any of various insulating materials. For example, the first insulation layer 282 may include or be formed of at least one of silicon oxide, silicon nitride, or silicon oxynitride. However, example embodiments are not limited thereto.

For example, among the plurality of wiring layers 286, a wiring layer 286 at an uppermost portion adjacent to the cell region 100 may include or constitute a pad portion to which the gate contact portion 184, the source contact portion 186, the through plug 188, or so on is connected.

Referring to FIG. 3 and FIG. 4 together with FIG. 1 and FIG. 2, the circuit region 200 that includes the plurality of transistors 300 will be described in more detail.

FIG. 3 is an enlarged cross-sectional view of a portion A in FIG. 1. FIG. 4 a cross-sectional view that illustrates one of a plurality of transistors 300 illustrated in FIG. 3. FIG. 3 illustrates a cross-sectional view of the circuit region 200 where a gate structure 310, a spacer 350, and source and drain regions 300s and 300d of the transistor 300 are positioned together. In FIG. 4, it is illustrated as an example that the transistor 300 has a structure of a first conductivity type transistor 400a.

Referring to FIG. 1 to FIG. 4, in some example embodiments, the semiconductor chip 10 (e.g., the circuit region 200) may include the first substrate 210, the plurality of transistors 300 that are disposed on the first substrate 210, and a cover layer 360. In the description, the plurality of transistors 300 and the cover layer 360 are separately described, but the cover layer 360 may be regarded as a partial portion of the transistor 300.

Each of the plurality of transistors 300 may include a gate structure 310 that is disposed on the first substrate 210 and a spacer 350 that is disposed on a side surface of the gate structure 310, and may further include source and drain regions 300s and 300d and/or a semiconductor layer 214. The gate structure 310 may include a gate insulation layer 312, a gate electrode 314, and a capping layer 316 that is disposed on the gate electrode 314 and includes an insulating material. The cover layer 360 may include a material different from a material of the spacer 350 and cover the gate structure 310 and the spacer 350.

In some example embodiments, the first substrate 210 may have a first surface 2101 and a second surface 2102 opposite to each other. A device isolator 212 may be disposed at a side of the first surface 2101 of the first substrate 210. The device isolator 212 may be at a boundary or boundaries of the plurality of transistors 300 to separate, divide, or define active regions of the plurality of transistors 300 at the side of the first surface 2101 of the first substrate 210. The active region may have a first conductivity type well or a second conductivity type well according to a conductivity type of a channel portion that is included in each transistor 300.

For example, the device isolator 212 may be an insulator having a shallow trench isolation (STI) structure for separating, dividing, or define the active regions of the transistors 300. The device isolator 212 may penetrate or pass through a partial portion of the first substrate 210. In the drawings, it is illustrated as an example that a first surface of the device isolator 212 at the side of the first surface 2101 of the first substrate 210 is disposed on the same plane as the first surface 2101 of the first substrate 210, but the example embodiments are not limited thereto. Depending on a process order of the device isolator 212, the first surface of the device isolator 212 may be disposed on a plane different from the first surface 2101 of the first substrate 210. For example, the first surface of the device isolator 212 may be disposed higher than the first surface 2101 of the first substrate 210.

For example, the device isolator 212 may include or be formed of at least one of silicon oxide, silicon nitride, silicon oxynitride, or a low dielectric constant material. The low dielectric constant material may be a material having a dielectric constant lower than a dielectric constant of silicon oxide. However, the example embodiments are not limited thereto. The device isolator 212 may include or be formed of any of various materials.

In some example embodiments, each transistor 300 may have a planar or substantially planar structure. That is, the gate structure 310 may horizontally extend, and the source and drain regions 300s and 300d may be disposed at both sides of the gate structure 310 in a plan view. For example, the source and drain regions 300s and 300d may be disposed at portions of the first substrate 210 at both sides of the gate structure 310 in a plan view. The transistor 300 having the planar or substantially planar structure may be stably applied to a memory device (e.g., a flash memory device) including the plurality of transistors 300 having various operating voltages or performing various acts.

In some example embodiments, in at least one of the plurality of transistors 300, the semiconductor layer 214 may be disposed between the first substrate 210 and the gate structure 310. For example, in a first conductivity type transistor 400a, the semiconductor layer 214 may be disposed between the first substrate 210 and the gate structure 310. The semiconductor layer 214 will be described in more detail later when the first conductivity type transistor 400a is described.

In some example embodiments, the gate structure 310 may include the gate insulation layer 312, the gate electrode 314, and the capping layer 316 that is disposed on the gate electrode 314. The capping layer 316 may include a first capping layer 316a that is disposed on an upper surface of the gate electrode 314, and may further include a second capping layer 316b that is disposed at least on a side surface of the gate electrode 314.

The gate insulation layer 312 may horizontally extend on the first surface 2101 of the first substrate 210. The gate electrode 314 may horizontally extend on the gate insulation layer 312. The first capping layer 316a may horizontally extend on the gate electrode 314. The second capping layer 316b may be disposed on side surfaces of the gate insulation layer 312, the gate electrode 314, and the first capping layer 316a and/or an upper surface of the first capping layer 316a.

The gate insulation layer 312 may be disposed between the first substrate 210 and the gate electrode 314, or between the semiconductor layer 214 and the gate electrode 314 on the first substrate 210. The gate insulation layer 312 may include an insulating material. The gate insulation layer 312 may include a single layer of a plurality of layers. In some example embodiments, there may be a difference in material or stacking structure of gate insulation layers 312 that are included in the first transistor 400 (e.g., a first conductivity type transistor 400a and/or a second conductivity type transistor 400b) and the second transistor 500. Further, there may be a difference in material or stacking structure of gate insulation layers 312 that are included in the first conductivity type transistor 400a and the second conductivity type transistor 400b. This will be described in more detail later when the first transistor 400 (e.g., the first conductivity type transistor 400a and the second conductivity type transistor 400b) and the second transistor 500 are described.

The gate electrode 314 that includes a conductive material may be disposed on the gate insulation layer 312. The gate electrode 314 may include a single layer of a plurality of layers.

In some example embodiments, the gate electrode 314 may include a base electrode layer 320 that includes a semiconductor layer and/or a metal-including layer, and may further include a buffer layer 330.

The base electrode layer 320 may include a material that has a high quality electrical conductivity and a relatively large thickness. For example, the base electrode layer 320 may include a single layer or a plurality of layers.

In some example embodiments, the base electrode layer 320 may include or be formed of at least one of metal, a metal alloy, metal nitride, metal silicide, or a doped semiconductor material. The metal or the metal alloy that is included in the base electrode layer 320 may include or be formed of at least one of Ti, W, Mo, Al, Cu, Ni, Mg, Co, Ta, Ru, Au, or Sr. However, example embodiments are not limited thereto. The doped semiconductor material may include or be formed of a semiconductor material (e.g., a polycrystalline semiconductor material) doped with an n-type dopant or a p-type dopant. The metal nitride that is included in the base electrode layer 320 may include or be formed of at least one of TiN, WN, MON, or TaN. However, example embodiments are not limited thereto. The base electrode layer 320 may further include metal oxide or metal oxynitride in which the above material is oxidized. However, example embodiments are not limited thereto.

In the drawings, it is illustrated as an example that the base electrode layer 320 includes a first electrode layer 322 that is formed of a semiconductor layer and a second electrode layer 324 that is formed of a metal layer. However, the example embodiments are not limited thereto. A material, a stacking structure, or so on of the base electrode layer 320 may be variously modified. For example, the base electrode layer 320 may further include a barrier layer that includes a metal layer and/or a metal nitride layer and is disposed between the first electrode layer 322 and the second electrode layer 324.

The buffer layer 330 may be disposed between the gate insulation layer 312 and the base electrode layer 320 and have a thickness less than a thickness of the base electrode layer 320. The base electrode layer 320 may perform a role in controlling work function and may be referred to as a work function control layer. The buffer layer 330 may include or be formed of a metal, metal oxide, metal nitride, metal oxynitride, metal carbide, or combination thereof. However, example embodiments are not limited thereto.

The buffer layer 330 may include a first buffer layer 332 and a second buffer layer 334 that have different work function. For example, the first buffer layer 332 may have first work function, and the second buffer layer 334 may have second work function less than or greater than the first work function. The first buffer layer 332 or the second buffer layer 334 may include a single layer or a plurality of layers.

The first buffer layer 332 may include or be formed of La, LaO, Ta, TaN, Nb, TiN, or so on, and the second buffer layer 334 may include or be formed of Ti, W, Ta, Al, Ru, Pt, TiN, TaN, TiC, TaC, or so on. However, the example embodiments are not limited thereto. The first buffer layer 332 or the second buffer layer 334 may include or be formed of any of various materials.

In some example embodiments, there may be a difference in material or stacking structure of gate electrodes 314 that are included in the first transistor 400 (e.g., the first conductivity type transistor 400a and/or the second conductivity type transistor 400b) and the second transistor 500. Further, there may be a difference in material or stacking structure of gate electrodes 314 that are included in the first conductivity type transistor 400a and the second conductivity type transistor 400b. This will be described in more detail later when the first transistor 400 (e.g., the first conductivity type transistor 400a and the second conductivity type transistor 400b) and the second transistor 500 are described.

The first capping layer 316a that is disposed on the gate electrode 314 may act as a mask layer in a patterning process of the gate insulation layer 312 and the gate electrode 314. The first capping layer 316a may be referred to as a mask layer. The first capping layer 316a may protect the gate electrode 314 on the upper surface of the gate electrode 314. For example, the first capping layer 316a may reduce and/or prevent an unwanted material or element (e.g., hydrogen) from penetrating into the gate electrode 314 or so on.

As in the above, the first capping layer 316a may be used as the mask layer, and the gate insulation layer 312, the gate electrode 314, and the first capping layer 316a may have the same or similar planar shape. The same or similar planar shape may refer to a case having the same planar shape and a case having a planar shape with a difference within a process error.

The first capping layer 316a may include any of various insulating materials. In some example embodiments, the first capping layer 316a may include a material different from a material of the spacer 350. The first capping layer 316a may include any of various insulating materials such as nitride, oxynitride, or so on. For example, the first capping layer 316a may include or be formed of at least one of silicon nitride or silicon oxynitride. However, the example embodiments are not limited thereto. A material of the first capping layer 316a may be variously modified.

The second capping layer 316b that is disposed on the side surfaces of the gate insulation layer 312, the gate electrode 314, and the first capping layer 316a and/or the upper surface of the first capping layer 316a may reduce and/or prevent an unwanted material or element (e.g., hydrogen) from penetrating into the gate structure 310, the first substrate 210, and/or the semiconductor layer 214.

In some example embodiments, after a patterning process of pattering the gate insulation layer 312, the gate electrode 314, and the first capping layer 316a is performed, the second capping layer 316b may be entirely formed on the first substrate 210, the semiconductor layer 214, the gate insulation layer 312, the gate electrode 314, and the first capping layer 316a. For example, the second capping layer 316b may include a side portion 316e that is disposed on the side surface of the gate structure 310, a first upper portion 316f that is disposed on the first capping layer 316a, and a second upper portion 316g that is disposed on the first surface 2101 of the first substrate 210 and/or the semiconductor layer 214. Thereby, an additional patterning process might not be needed in a process of forming the second capping layer 316b and a manufacturing process of the second capping layer 316b may be simplified.

In some example embodiments, the second capping layer 316b may include the side portion 316e, but the first upper portion 316f and/or the second upper portion 316g may be omitted. In some example embodiments, the second capping layer 316b may be omitted. However, example embodiments are not limited thereto. The second capping layer 316b may include any of various insulating materials. In some example embodiments, the second capping layer 316b may include a material different from a material of the spacer 350. For example, the second capping layer 316b may include or be formed of at least one of nitride (e.g., silicon nitride) or oxynitride (e.g., silicon oxynitride). However, the example embodiments are not limited thereto. A material of the second capping layer 316b may be variously modified.

In some example embodiments, the capping layer 316 may include a portion (e.g., the first capping layer 316a and the first upper portion 316f) that is disposed on the gate electrode 314. In the vertical direction (the Z-axis direction) that is perpendicular to the first substrate 210, the portion of the capping layer 316 that is disposed on the gate electrode 314 may have a first surface 3161 that is opposite to the gate electrode 314 and a second surface 3162 that is adjacent to the gate electrode 314.

In some example embodiments, the capping layer 316 may include the first capping layer 316a and the second capping layer 316b. The first surface 3161 of the capping layer 316 may be or correspond to an upper surface of the second capping layer 316b, and the second surface 3162 of the capping layer 316 may be or correspond to a lower surface of the first capping layer 316a. However, the example embodiments are not limited thereto. When the capping layer 316 includes the first capping layer 316a and might not include the second capping layer 316b, the first surface 3161 of the capping layer 316 may be or correspond to an upper surface of the first capping layer 316a, and the second surface 3162 of the capping layer 316 may be or correspond to a lower surface of the first capping layer 316a. When the capping layer 316 includes an additional capping layer on or under the first capping layer 316a and/or on the second capping layer 316b, at least one of the first surface 3161 of the capping layer 316 or the second surface 3162 of the capping layer 316 may be or correspond to an upper surface or a lower surface of the additional capping layer.

The spacer 350 may be disposed on at least the side surface of the gate structure 310 (e.g., at least a side surface of the gate electrode 314). More particularly, the spacer 350 may be disposed on the upper surface and/or the side surface of the first substrate 210 and/or the semiconductor layer 214, and on the second capping layer 316b that is disposed on the side surfaces of the gate insulation layer 312, the gate electrode 314, and the first capping layer 316a.

The spacer 350 may electrically insulate the gate structure 310 (e.g., the gate electrode 314) and the source and drain regions 300s and 300d. For example, in a plan view, the spacer 350 may be disposed at least at both sides, respectively, in a crossing direction or a transverse direction that crosses or is transverse to an extension direction of the gate electrode 314 between the gate electrode 314 and the source and drain regions 300s and 300d. In a plan view, the spacer 350 may extend in the extension direction of the gate structure 310.

The spacer 350 may include any of various insulating materials such as oxide, nitride, oxynitride, and a low dielectric constant material, or so on. For example, the spacer 350 may include or be formed of a material that includes at least one of silicon oxide, silicon nitride, or silicon oxynitride, or a material in which carbon is additionally included in the above material. The spacer 350 may include one insulation layer or may include a plurality of insulation layers. However, the example embodiments are not limited thereto. The spacer 350 may include any of various materials other than the above material.

The source and drain regions 300s and 300d may be formed of doping regions formed by doping partial portions of the first substrate 210. For example, the source and drain regions 300s or 300d may be portions formed by doping an n-type dopant or a p-type dopant to the partial portions of the first substrate 210. A dopant of the source and drain regions 300s and 300d may have a conductivity type opposite to a conductive type of the active region (e.g., the first conductivity type well or the second conductivity type well) of the transistor 300. However, the example embodiments are not limited thereto. The source and drain regions 300s and 300d may include any of various materials or have any of various structures or so on.

The cover layer 360 may be disposed at least on an upper surface of the gate structure 310 and on an outer side surface 3503 of the spacer 350. The upper surface of the gate structure 310 may be a surface of the gate structure 310 that is opposite to the first substrate 210, and the outer side surface 3503 of the spacer 350 may be a surface of the spacer 350 that connects an upper end 3501 of the spacer 350 (more particularly, an upper end 3501 of the spacer 350 at an inner side surface of the spacer 350) and an outer end 3502 of the spacer 350 at a bottom surface of the spacer 350. The inner side surface of the spacer 350 may refer to a surface that is adjacent to the side surface of the gate structure 310 (e.g., the side portion 316e of the second capping layer 316b), and the bottom surface of the spacer 350 may refer to a surface that is adjacent to the first substrate 210 and/or the semiconductor layer 214.

In some example embodiments, the cover layer 360 may be a kind of a capping layer that prevents an unwanted material or element (e.g., hydrogen) from penetrating into the gate structure 310, the first substrate 210, and/or the semiconductor layer 214. The cover layer 360 may be a stopping layer (e.g., a polishing stopping layer in a polishing process) in a removal process of removing a partial portion of a first interlayer insulation layer 282m. This will be described in more detail.

The cover layer 360 may include any of various insulating materials. In some example embodiments, the cover layer 360 may include a material different from a material of the spacer 350. The cover layer 360 may include or be formed of any of various insulating materials such as nitride, oxynitride, or so on. For example, the cover layer 360 may include or be formed of at least one of silicon nitride or silicon oxynitride. When the cover layer 360 includes silicon nitride, the cover layer 360 may effectively reduce and/or prevent hydrogen included in a first insulation layer 282 from penetrating into the gate structure 310 and/or the source and drain regions 300s and 300d. However, the example embodiments are not limited thereto. The cover layer 360 may include any of various materials.

In some example embodiments, after the gate structure 310, the second capping layer 316b, and/or the spacer 350 is formed, the cover layer 360 may be entirely formed on the first substrate 210 and/or the semiconductor layer 214. For example, the cover layer 360 may include a side cover portion 362, a first upper cover portion 364, and a second upper cover portion 366. The side cover portion 362 may be disposed on the outer side surface 3503 of the spacer 350. The first upper cover portion 364 may be disposed on the upper surface of the gate structure 310 (e.g., on the first upper portion 316f) that is opposite to the first surface 2101 of the first substrate 210. The second upper cover portion 366 may be disposed on the first surface 2101 of the first substrate 210 and/or on the semiconductor layer 214. Thereby, an additional patterning process might not be needed in a process of forming the cover layer 360 and a manufacturing process of the cover layer 360 may be simplified.

In some example embodiments, the cover layer 360 may include the side cover portion 362 and the first upper cover portion 364, but the second upper cover portion 366 may be omitted. However, the example embodiments are not limited thereto.

When the first capping layer 316a and the second capping layer 316b may include different materials and/or the cover layer 360 may include different materials, a boundary of the first capping layer 316a and the second capping layer 316b and/or a boundary of the second capping layer 316b and the cover layer 360 may be seen or confirmed by a difference in material.

Even when the first capping layer 316a and the second capping layer 316b may include the same material and/or the cover layer 360 may include the same material, the boundary of the first capping layer 316a and the second capping layer 316b and/or the boundary of the second capping layer 316b and the cover layer 360 may be seen or confirmed by a difference in composition, manufacturing process condition, or so on. Even when there may be no difference in composition, manufacturing process condition, or so on, the first capping layer 316a, the second capping layer 316b, and/or the cover layer 360 may be formed by a separate process, and thus, the boundary of the first capping layer 316a and the second capping layer 316b and/or the boundary of the second capping layer 316b and the cover layer 360 may be seen or confirmed. For example, even when each of the first capping layer 316a, the second capping layer 316b, and/or the cover layer 360 may include or be formed of nitride (e.g., silicon nitride), at least a partial portion of the first capping layer 316a, the second capping layer 316b, and/or the cover layer 360 may be seen or confirmed.

For example, after a preliminary spacer layer that includes a material different from a material of the capping layer 316 is formed on the capping layer 316, the spacer 350 may be formed by patterning the preliminary spacer layer. The first surface 3161 of the capping layer 316 may be seen or confirmed in a final structure by a property change of the first surface 3161 of the capping layer 316 that may be induced in a process of forming the preliminary spacer layer.

Even when the boundary of the first capping layer 316a and the second capping layer 316b and/or the boundary of the second capping layer 316b and the cover layer 360 may be difficult to be physically seen or confirmed in the final structure, the boundary of the first capping layer 316a and the second capping layer 316b and/or the boundary of the second capping layer 316b and the cover layer 360 may be expected or determined.

When the boundary of the first capping layer 316a and the second capping layer 316b and/or the boundary of the second capping layer 316b and the cover layer 360 may be difficult to be physically seen or confirmed in the final structure, an upper insulation portion that includes a material different from materials the gate electrode 314 and the first interlayer insulation layer 282m may be disposed on an upper portion of the gate electrode 314. The upper insulation portion may include the first capping layer 316a, the first upper portion 316f of the second capping layer 316b, and/or the first upper cover portion 364 of the cover layer 360.

When a portion that includes a material different from materials of the spacer 350 and the first interlayer insulation layer 282m is seen or confirmed between the spacer 350 and the first interlayer insulation layer 282m, the portion may be or correspond to the side cover portion 362 of the cover layer 360. A thickness of the first upper cover portion 364 of the cover layer 360 may be substantially the same as a thickness of the side cover portion 362 of the cover layer 360. Accordingly, a surface that is spaced apart from an upper surface of the upper insulation portion by the thickness of the first upper cover portion 364 of the cover layer 360 may be expected or determined as the first surface 3161 of the capping layer 316.

Accordingly, the first surface 3161 and the second surface 3162 of the capping layer 316 that are opposite to each other may be confirmed or determined.

The first insulation layer 282 may be disposed to cover the plurality of transistors 300 and the cover layer 360. A plurality of contact vias 284 may penetrate or pass through the first insulation layer 282 and be electrically connected to the plurality of transistors 300, respectively. For a clear understanding and simple illustration, in the drawings, the plurality of contact vias 284 electrically connected to the source and drain regions 300s and 300d are illustrated. The plurality of contact vias 284 may be electrically connected to the source and drain regions 300s and 300d, and the gate electrode 314, respectively. The contact via 284 electrically connected to the gate electrode 314 may penetrate or pass through the first insulation layer 282, the cover layer 360, and the capping layer 316 and be connected to the gate electrode 314.

In some example embodiments, the first insulation layer 282 may include a first interlayer insulation layer 282m, and one or a plurality of second interlayer insulation layers 282n that are disposed on the first interlayer insulation layer 282m. A first surface of the first interlayer insulation layer 282m may be disposed on the same plane as a first surface (e.g., the first surface 3601 of the cover layer 360) of a highest transistor of the plurality of transistors 300. The highest transistor may have the greatest height (e.g., a first height H1). For example, the highest transistor may be a first conductivity type transistor 400a. A boundary of the first interlayer insulation layer 282m and the second interlayer insulation layer 282n may be seen or confirmed in a final structure, or might not be seen or confirmed in the final structure.

In some example embodiments, the plurality of transistors 300 may include a first transistor 400 and a second transistor 500. The second transistor 500 may have an operating voltage greater than an operating voltage of the first transistor 400.

The first transistor 400 may be a low voltage (LV) transistor having a relatively low operating voltage, and the second transistor 500 may be a high voltage (HV) transistor having a relatively high operating voltage. For example, the operating voltage of the first transistor 400 may be in a range of about 0.1V to about 10V, and the operating voltage of the second transistor 500 may be greater than the operating voltage of the first transistor 400 and be in a range of about 10V to about 100V. However, the example embodiments are not limited to the range of the operating voltage of the first transistor 400 and/or the second transistor 500.

In some example embodiments, the first transistor 400, which is the low voltage transistor, may have a high-speed operation property and higher reliability, and may be applied to a transistor that may require high-speed operation. For example, at least a part of transistors included in the decoder circuit 1110 (refer to FIG. 15), the page buffer 1120 (refer to FIG. 15), or the logic circuit 1130 (refer to FIG. 15) may be the first transistor 400.

For example, the first transistor 400 may include a first conductivity type transistor 400a and a second conductivity type transistor 400b. In the first conductivity type transistor 400a, the source and drain regions 300s and 300d may have the first conductivity type, and the active region may be formed of the second conductivity type well that has the second conductivity type opposite to the first conductivity type. In the second conductivity type transistor 400b, the source and drain regions 300s and 300d may have the second conductivity type, and the active region may be formed of the first conductivity type well that has the first conductivity type. For example, the first conductivity type may be a p-type and the second conductivity type may be an n-type. Thereby, the first conductivity type transistor 400a may be a p-type metal oxide semiconductor (PMOS) transistor, and the second conductivity type transistor 400b may be an n-type metal oxide semiconductor (NMOS) transistor. However, the example embodiments are not limited thereto.

The second transistor 500, which is the high voltage transistor, may be applied to a transistor that generates or transmits a high voltage. For example, at least a part of transistors included in the decoder circuit 1110 (refer to FIG. 15), the page buffer 1120 (refer to FIG. 15), or so on may be the second transistor 500. For example, the second transistor 500 may be a pass transistor that applies a voltage to the gate electrode layer 130 included in the gate stacking structure 120.

For a clear understanding and simple illustration, in the drawings, it is illustrated as an example that the first transistor 400 is disposed at a lower portion of the cell array region 102, and the second transistor 500 is disposed at a lower portion of the connection region 104. However, the example embodiments are not limited thereto. For example, at least one of the first transistor 400 or the second transistor 500 may be disposed at the lower portion of the cell array region 102, or at least one of the first transistor 400 or the second transistor 500 may be disposed at the lower portion of the connection region 104. Positions of the first transistor 400 and the second transistor 500 may be variously modified.

In some example embodiments, the gate insulation layer 312 (e.g., a first gate insulation layer 412) that is included in the first transistor 400 and the gate insulation layer 312 (e.g., a second gate insulation layer 512) that is included in the second transistor 500 may have different materials, stacking structures, or thicknesses. The gate electrode 314 (e.g., a first gate electrode 414) included in the first transistor 400 and the gate electrode 314 (e.g., a second gate electrode 514) included in the second transistor 500 may include different materials, or have stacking structures or thicknesses. The first gate electrode 414 of the first conductivity type transistor 400a and the first gate electrode 414 of the second conductivity type transistor 400b may have different materials or stacking structures. Semiconductor material layers (e.g., the first substrate 210 and/or the semiconductor layer 214) included in the first conductivity type transistor 400a and the second conductivity type transistor 400b may have different materials or stacking structures.

In the specification, the phrase that a first portion and a second portion include different materials or having different stacking structures may refer to a case that a number of a layer or layers included in the first portion is different from a number of a layer or layers included in the second portion, a layer including a material that is not included in the first portion is included in the second portion, a layer including a material that is not included in the second portion is included in the first portion, at least one layer of a plurality of layers that are included in the first portion is not included in the second portion, or at least one layer of a plurality of layers that are included in the second portion is not included in the first portion.

In some example embodiments, there may be a difference in presence or absence of the semiconductor layer 214 in the first conductivity type transistor 400a and the second conductivity type transistor 400b. For example, in the first conductivity type transistor 400a of the PMOS transistor, the semiconductor layer 214 may be disposed between the first substrate 210 and the first gate insulation layer 412. The semiconductor layer 214 included in the first conductivity type transistor 400a may control (e.g., reduce) a threshold voltage in the first conductivity type transistor 400a of the PMOS transistor. In the second conductivity type transistor 400b of the NMOS transistor, the semiconductor layer 214 might not be disposed between the first substrate 210 and the first gate insulation layer 412. For example, the first gate insulation layer 412 may be in contact with each of the first substrate 210 and a first gate electrode 414 between the first substrate 210 and the first gate electrode 414.

The semiconductor layer 214 may include a semiconductor material that includes a material different from the semiconductor material of the first substrate 210 or have a composition different from a composition of the semiconductor material of the first substrate 210. For example, the semiconductor layer 214 may include or be formed of germanium, silicon-germanium, or so on. A material of the semiconductor layer 214 may be variously modified.

The first gate insulation layer 412 included in the first transistor 400 may include a single layer or a plurality of layers.

The first gate insulation layer 412 may include or be formed of a high dielectric constant insulation layer (a high-k insulation layer) 412a. The high dielectric constant insulation layer 412a may have a dielectric constant greater than a dielectric constant of a material (e.g., silicon oxide) that is included in at least a partial portion of the second gate insulation layer 512 in the second transistor 500. The first gate insulation layer 412 may further include an interfacial layer 412b.

The high dielectric constant insulation layer 412a may include or be formed of at least one of hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AIO), or lead scandium tantalum oxide (PbScTaO). However, example embodiments are not limited thereto.

The interfacial layer 412b may be disposed between the first substrate 210 and the high dielectric constant insulation layer 412a or between the semiconductor layer 214 and the high dielectric constant insulation layer 412a, thereby enhancing an interface property of the first gate insulation layer 412. For example, in the first conductivity type transistor 400a, the interfacial layer 412b may be in contact with each of the semiconductor layer 214 and the high dielectric constant insulation layer 412a between the semiconductor layer 214 and the high dielectric constant insulation layer 412a. In the second conductivity type transistor 400b, the interfacial layer 412b may be in contact with each of the first substrate 210 and the high dielectric constant insulation layer 412a between the first substrate 210 and the high dielectric constant insulation layer 412a. However, the example embodiments are not limited thereto. The interfacial layer 412b may be omitted.

The interfacial layer 412b may have a dielectric constant less than a dielectric constant of the high dielectric constant insulation layer 412a. For example, the interfacial layer 412b may include or be formed of at least one of oxide (e.g., silicon oxide) or oxynitride (e.g., silicon oxynitride). However, example embodiments are not limited thereto.

The first gate electrode 414 included in the first transistor 400 may include the base electrode layer 320 and the buffer layer 330. The first gate insulation layer 412 may include the high dielectric constant insulation layer 412a and the second gate electrode 514 may further include the buffer layer 330.

In some example embodiments, the buffer layers 330 included in the first conductivity type transistor 400a and the second conductivity type transistor 400b may include different materials, or have stacking structures or structures. For example, in the first conductivity type transistor 400a and the second conductivity type transistor 400b, there may be a difference in number, stacking structure, or so on of the first buffer layer 332 and/or the second buffer layer 334 that is included in the buffer layer 330.

For a clear understanding, in the drawings, it is illustrated as an example that the first conductivity type transistor 400a of the PMOS transistor includes the second buffer layer 334, the first buffer layer 332, and the second buffer layer 334 that are sequentially stacked, and the second conductivity type transistor 400b of the NMOS transistor includes the first buffer layer 332 and the second buffer layer 334 that are sequentially stacked. However, the example embodiments are not limited thereto. In the first conductivity type transistor 400a, a material or a stacking structure of the first buffer layer 332 and the second buffer layer 334 included in the buffer layer 330 may be variously modified. In the second conductivity type transistor 400b, a material or a stacking structure of the first buffer layer 332 and the second buffer layer 334 included in the buffer layer 330 of the second conductivity type transistor 400b may be variously modified.

In some example embodiments, the first transistor 400 may include the high dielectric constant insulation layer 412a and the second electrode layer 324 to have a high dielectric constant metal gate (high-k metal gate, HKMG) structure. The high dielectric constant insulation layer 412a may include or be formed of a high dielectric constant material, and the second electrode layer 324 may include or be formed of a metal layer. By the high dielectric constant insulation layer 412a, a thickness of the high dielectric constant insulation layer 412a may be reduced and a high quality electrical insulation property may be maintained. By the second electrode layer 324, performance of the first transistor 400 may be enhanced and a size of the first transistor 400 may be reduced.

Since the first transistor 400 of the low voltage transistor capable of performing the high speed operation may have the high dielectric constant metal gate structure, a speed may be effectively enhanced. Thereby, performance of the first transistor 400 may be enhanced. When the first transistor 400 may have the high dielectric constant metal gate structure, which is different from a structure of the second transistor 500, a large number of transistors 300 having different structures or heights may be included.

The second gate insulation layer 512 included in the second transistor 500 may include a material different from a material of the first gate insulation layer 412 included in the first transistor 400, or have a stacking structure or a thickness different from a stacking structure or a thickness of the first gate insulation layer 412 included in the first transistor 400.

The second gate insulation layer 512 may include or be formed of at least one of oxide, nitride, oxynitride, or a low dielectric constant material having a lower dielectric constant than silicon oxide. For example, the second gate insulation layer 512 may include or be formed of at least one of silicon oxide, silicon nitride, or silicon oxynitride. However, example embodiments are not limited thereto. The second gate insulation layer 512 may include a single layer or a plurality of layers.

The second gate electrode 514 included in the second transistor 500 may include the base electrode layer 320 and might not include the buffer layer 330. For example, the base electrode layer 320 of the second gate electrode 514 may be disposed between the second gate insulation layer 512 and the first capping layer 316a. For example, the base electrode layer 320 of the second gate electrode 514 may be in contact with each of the second gate insulation layer 512 and the first capping layer 316a.

A thickness of the second gate insulation layer 512 may be greater than a thickness of the first gate insulation layer 412. A channel length (a distance between the source region 300s and the drain region 300d) in the second transistor 500 may be greater than a channel length (a distance between the source region 300s and the drain region 300d) in the first transistor 400. In the crossing direction or the transverse direction that crosses or is transverse to the extension direction of the gate electrode 314, a width of the second gate electrode 514 may be greater than a width of the first gate electrode 414. Thereby, the second transistor 500 of the high voltage transistor may stably withstand a high potential difference between the second gate electrode 514 and the source and drain regions 300s and 300d.

In some example embodiments, the first surface 2101 of the first substrate 210 in a portion where the first transistor 400 is disposed may be higher than the first surface 2101 of the first substrate 210 in a portion where the second transistor 500 is disposed. That is, in the vertical direction (the Z-axis direction) that is perpendicular to the first substrate 210, a lower surface of the gate structure 310 (e.g., the first gate structure 410) and/or a surface of the semiconductor layer 214 that is adjacent to the first surface 2101 of the first substrate 210 in the portion where the first transistor 400 is disposed may be disposed at a first substrate height HS1. In the vertical direction, a lower surface of the gate structure 310 (e.g., the second gate structure 510) that is adjacent to the first surface 2101 of the first substrate 210 in the portion where the second transistor 500 is disposed may be disposed at a second substrate height HS2, which is lower than the first substrate height HS1. Thereby, the second transistor 500 that includes the second gate insulation layer 512 having a relatively large thickness may be easily formed. However, the example embodiments are not limited thereto. The first surface 2101 of the first substrate 210 in the portion where the first transistor 400 is disposed may be the same plane as the first surface 2101 of the first substrate 210 in the portion where the second transistor 500 is disposed. Other various modifications are possible.

In some example embodiments, the plurality of transistors 300 may have different heights. That is, the first conductivity type transistor 400a, the second conductivity type transistor 400b, and/or the second transistor 500 may have different stacking structures and may have different heights. The height of the transistor 300 may refer to a position of the first surface 3601 of the cover layer 360 that is disposed on the gate structure 310 in the vertical direction (the Z-axis direction) that is perpendicular to the first substrate 210. The height of the transistor 300 may be varied depending on a height of the first surface 2101 of the first substrate 210, a presence or an absence of the semiconductor layer 214, a thickness of the gate insulation layer 312, a thickness of the gate electrode 314, a stacking structure, or so on.

In some example embodiments, the first transistor 400 may have a relatively high height, and the second transistor 500 may have a height less than the height of the first transistor 400.

For example, in the first conductivity type transistor 400a, the first surface 2101 of the first substrate 210 may have the first substrate height HS1, which is relatively large, the semiconductor layer 214 may be further included, and the gate electrode 314 may include the base electrode layer 320 and the buffer layer 330. A thickness of the buffer layer 330 included in the first conductivity type transistor 400a may be greater than a thickness of the buffer layer 330 included in the second conductivity type transistor 400b. Accordingly, the first conductivity type transistor 400a may have a first height H1, which is relatively large.

For example, in the second conductivity type transistor 400b, the first surface 2101 of the first substrate 210 may have the first substrate height HS1, which is relatively large, the semiconductor layer 214 might not be included, and the gate electrode 314 may include the base electrode layer 320 and the buffer layer 330. The thickness of the buffer layer 330 included in the second conductivity type transistor 400b may be less than the thickness of the buffer layer 330 included in the first conductivity type transistor 400a. Accordingly, the second conductivity type transistor 400b may have a second height H2, which is less than the first height H1.

For example, in the second transistor 500, the first surface 2101 of the first substrate 210 may have the second substrate height HS2, which is relatively small, the semiconductor layer 214 might not be included, and the gate electrode 314 includes the base electrode layer 320 and might not include the buffer layer 330. Accordingly, the second transistor 500 may have a third height H3, which is less than the second height H2.

In the description, it is described as an example that the first conductivity type transistor 400a, which is the low voltage transistor and the PMOS transistor, has the first height H1, the second conductivity type transistor 400b, which is the low voltage transistor and the NMOS transistor, has the second height H2 less than the first height H1, and the second transistor 500 of the high voltage transistor has the third height H3 less than the second height H2. This may be an example, and heights of the first conductivity type transistor 400a, the second conductivity type transistor 400b, and the second transistor 500 may be different from the heights described in the above.

For a clear understanding, in the drawings, it is illustrated as an example that one first conductivity type transistor 400a has the first height H1, one second conductivity type transistor 400b has the second height H2, and a plurality of second transistors 500 have the same height, that is, the third height H3. However, the example embodiments are not limited thereto.

For example, a plurality of first conductivity type transistors 400a having different heights may be provided. In at least two first conductivity type transistors 400a, a thickness or a stacking structure of the semiconductor layer 214 may be different, a thickness or a stacking structure of the first gate insulation layer 412 may be different, or a thickness or a stacking structure of the first gate electrodes 414 may be different. In at least one of the plurality of first conductivity type transistors 400a, an additional layer may be disposed between the first substrate 210 and the semiconductor layer 214, between the semiconductor layer 214 and the first gate insulation layer 412, and/or between the first gate insulation layer 412 and the first gate electrode 414.

For example, a plurality of second conductivity type transistors 400b having different heights may be provided. In at least two second conductivity type transistors 400b, a thickness or a stacking structure of the semiconductor layer 214 may be different, a thickness or a stacking structure of the first gate insulation layer 412 may be different, or a thickness or a stacking structure of the first gate electrodes 414 may be different. In at least one of the plurality of second conductivity type transistors 400b, an additional layer may be disposed between the first substrate 210 and the first gate insulation layer 412, and/or between the first gate insulation layer 412 and the first gate electrode 414.

For example, a plurality of second transistors 500 having different heights may be provided. In at least two second transistors 500, a thickness or a stacking structure of the second gate insulation layer 512 may be different, or a thickness or a stacking structure of the second gate electrodes 514 may be different. In at least one of the plurality of second transistors 500, an additional layer may be disposed between the first substrate 210 and the second gate insulation layer 512, and/or between the second gate insulation layer 512 and the second gate electrode 514.

In the semiconductor chip 10 (e.g., the flash memory device) that includes the plurality of transistors 300 having various acts, the plurality of transistors 300 may have different structures to perform various acts. Accordingly, the semiconductor chip 10 (e.g., the flash memory device) may include the plurality of transistors 300 having different heights.

In some example embodiments, when the plurality of transistors 300 having different heights are provided, the plurality of transistors 300 may have a structure in which the cover layer 360 may be stably remained in a process of forming the first interlayer insulation layer 282m.

In FIG. 4, it is illustrated as an example that the transistor 300 has a structure of the first conductivity type transistor 400a. In the description with reference to FIG. 4, the description of the transistor 300 may be applied to the first transistor 400 (e.g., the first conductivity type transistor 400a or the second conductivity type transistor 400b) or the second transistor 500.

For example, in the description with reference to FIG. 4, the description of the spacer 350 and the gate structure 310, and the cover layer 360 disposed thereon may be applied to the spacer 350 and the first gate structure 410, and the cover layer 360 disposed thereon that are included in the first transistor 400 (e.g., the first conductivity type transistor 400a or the second conductivity type transistor 400b). For example, in the description with reference to FIG. 4, the description of the spacer 350 and the gate structure 310, and the cover layer 360 disposed thereon may be applied to the spacer 350 and the second gate structure 510, and the cover layer 360 disposed thereon that are included in the second transistor 500.

In some example embodiments, in the transistor 300, in the vertical direction (the Z-axis direction) that is perpendicular to the first substrate 210, the spacer 350 may be spaced apart from the first surface 3161 of the capping layer 316 by a first separation distance D1. In some example embodiments, the spacer 350 may have a partial recess structure in which an upper portion of the spacer 350 has a partial recess. For example, the spacer 350 may be an oxide spacer having the partial recess structure.

More particularly, in the vertical direction (the Z-axis direction) that is perpendicular to the first substrate 210, the upper end 3501 of the spacer 350 that is adjacent to the gate structure 310 may be disposed between the first surface 3161 of the capping layer 316 and the second surface 3162 of the capping layer 316. Accordingly, in the vertical direction that is perpendicular to the first substrate 210, the upper end 3501 of the spacer 350 may be spaced apart from the first surface 3161 of the capping layer 316 by the first separation distance D1, and may be spaced apart from the second surface 3162 of the capping layer 316 by a second separation distance D2. Thereby, the spacer 350 and the cover layer 360 may be entirely disposed on the side surface of the gate electrode 314, and stably protect the gate electrode 314. However, the example embodiments are not limited thereto. In some example embodiments, the vertical direction (the Z-axis direction) that is perpendicular to the first substrate 210, the upper end 3501 of the spacer 350 that is adjacent to the gate structure 310 may be disposed at a lower portion of the second surface 3162 of the capping layer 316. Other various modifications are possible.

At least in the first conductivity type transistor 400a having the first height H1, which is relatively large, the upper end 3501 of the spacer 350 may be spaced apart from the first surface 3161 of the capping layer 316. For example, in the first conductivity type transistor 400a, the upper end 3501 of the spacer 350 may be disposed between the first surface 3161 of the capping layer 316 and the second surface 3162 of the capping layer 316.

In the second conductivity type transistor 400b having the second height H2 less than the first height H1, the upper end 3501 of the spacer 350 may be spaced apart from the first surface 3161 of the capping layer 316. For example, in the second conductivity type transistor 400b, the upper end 3501 of the spacer 350 may be disposed between the first surface 3161 of the capping layer 316 and the second surface 3162 of the capping layer 316. In the second transistor 500 having the third height H3 less than the first height H1 and the second height H2, the upper end 3501 of the spacer 350 may be spaced apart from the first surface 3161 of the capping layer 316. For example, in the second transistor 500, the upper end 3501 of the spacer 350 may be disposed between the first surface 3161 of the capping layer 316 and the second surface 3162 of the capping layer 316.

In each of the plurality of transistors 300, the upper end 3501 of the spacer 350 may be spaced apart from the first surface 3161 of the capping layer 316. For example, in each of the plurality of transistors 300, the upper end 3501 of the spacer 350 may be disposed between the first surface 3161 of the capping layer 316 and the second surface 3162 of the capping layer 316.

A side surface of the capping layer 316 may include a first side portion S1 and a second side portion S2. On the first side portion S1, the spacer 350 and the cover layer 360 may be disposed together. The second side portion S2 may be disposed on the first side portion S1 in the vertical direction (the Z-axis direction) that is perpendicular to the first substrate 210. On the second side portion S2, the cover layer 360 may be disposed. In the specification, the side surface of the capping layer 316 may refer to the side surface of the capping layer 316 in a portion of the capping layer 316 that is disposed on the gate electrode 314. That is, the side surface of the capping layer 316 may include the second side portion S2 on which the cover layer 360 is disposed without the spacer 350.

More particularly, in the side surface of the capping layer 316, a lower portion of the upper end 3501 of the spacer 350 may include the first side portion S1 on which the spacer 350 and the cover layer 360 are disposed together. In the side surface of the capping layer 316, an upper portion of the upper end 3501 of the spacer 350 may include the second side portion S2 on which the cover layer 360 is disposed.

For example, the spacer 350 may be in contact with the capping layer 316 (e.g., the first side portion S1) in the first side portion S1, and the cover layer 360 may be in contact with the capping layer 316 (e.g., the second side portion S2) in the second side portion S2. However, the example embodiments are not limited thereto. An additional layer may be further included between the first side portion S1 and the spacer 350 and/or between the second side portion S2 and the cover layer 360.

At least in the first conductivity type transistor 400a having the first height H1, which is relatively large, the side surface of the capping layer 316 may include the first side portion S1 and the second side portion S2. In the second conductivity type transistor 400b having the second height H2 less than the first height H1, the side surface of the capping layer 316 may include the first side portion S1 and the second side portion S2. In the second transistor 500 having the third height H3 less than the first height H1 and the second height H2, the side surface of the capping layer 316 may include the first side portion S1 and the second side portion S2. In each of the plurality of transistors 300, the side surface of the capping layer 316 may include the first side portion S1 and the second side portion S2.

Accordingly, the side cover portion 362 of the cover layer 360 may include a first cover portion 362a and a second cover portion 362b. The first cover portion 362a may be disposed on (e.g., be in contact with) the spacer 350. The second cover portion 362b may be disposed on (e.g., be in contact with) the side surface of the capping layer 316 without the spacer 350. This may be different from a structure of a comparative example where an upper end of a spacer reaches a first surface of a capping layer in a vertical direction and a side cover portion of a cover layer is entirely disposed on the spacer.

At least in the first conductivity type transistor 400a having the first height H1, which is relatively large, the side cover portion 362 of the cover layer 360 may include the first cover portion 362a and the second cover portion 362b. The first cover portion 362a may be disposed on the spacer 350 (e.g., an outer surface of the spacer 350). The second cover portion 362b may be disposed on the side surface of the capping layer 316 without the spacer 350. In the second conductivity type transistor 400b having the second height H2 less than the first height H1, the side cover portion 362 of the cover layer 360 may include the first cover portion 362a and the second cover portion 362b. The first cover portion 362a may be disposed on the spacer 350. The second cover portion 362b may be disposed on the side surface of the capping layer 316 without the spacer 350. In the second transistor 500 having the third height H3 less than the first height H1 and the second height H2, the side cover portion 362 of the cover layer 360 may include the first cover portion 362a and the second cover portion 362b. The first cover portion 362a may be disposed on the spacer 350. The second cover portion 362b may be disposed on the side surface of the capping layer 316 without the spacer 350. In each of the plurality of transistors 300, the side cover portion 362 of the cover layer 360 may include the first cover portion 362a and the second cover portion 362b. The first cover portion 362a may be disposed on the spacer 350. The second cover portion 362b may be disposed on the side surface of the capping layer 316 without the spacer 350.

In some example embodiments, the outer side surface 3503 of the spacer 350 may have a convex shape that is convex to an outside, and the side cover portion 362 of the cover layer 360 may have an inflection point or have a concave portion that is concave to be opposite to the convex shape of the spacer 350. For example, the first cover portion 362a that is disposed on t the spacer 350 on the side surface of the capping layer 316 may have a convex shape the same as or similar to the convex shape of the spacer 350. The inflection portion IP may be disposed at a portion where the first cover portion 362a and the second cover portion 362b are connected. In at least a partial portion of the second cover portion 362b (e.g., a portion of the second cover portion 362b that is adjacent to the first cover portion 362a), the concave portion that is concave to be opposite to the convex shape of the spacer 350 may be provided.

As described in the above, the upper end 3501 of the spacer 350 may be spaced apart from the first surface 3161 of the capping layer 316, and the second side portion S2 may be disposed on a side surface of an upper portion of the gate structure 310 (e.g., a side surface of an upper portion of the capping layer 316). In the second side portion S2, the cover layer 360 may be disposed without the spacer 350. By the second cover portion 362b of the cover layer 360 that is disposed on the second side portion S2, a height HC of the cover layer 360 that is disposed on the upper portion of the spacer 350 may be sufficient to protect the spacer 350. Thereby, a thickness T2 or the height TC of the cover layer 360 may be set during the process of forming the first interlayer insulation layer 282m. As a result, performance and/or reliability of the transistor 300 may be maintained. The height HC of the cover layer 360 may refer to a height (e.g., a maximum height) in the vertical direction (the Z-axis direction in the drawings) that is perpendicular to the first substrate 210, and the thickness T2 of the cover layer 360 may refer to a thickness (e.g., a maximum thickness) of the cover layer 360 in a direction perpendicular to the cover layer 360.

More particularly, in the process of forming the first interlayer insulation layer 282m, a removal process (e.g., a chemical mechanical polishing process) of removing a partial portion of the first interlayer insulation layer 282m may be performed to planarize the first interlayer insulation layer 282m. The removal process may be stopped at the first surface 3601 of the cover layer 360 by using the cover layer 360 as a stopping layer (e.g., a polishing stopping layer) in the removal process of the first interlayer insulation layer 282m. By a process error or so on, the removal process might not be stopped at the first surface 3601 of the cover layer 360, and the cover layer 360 may be undesirably removed. Even if the cover layer 360 is undesirably removed more than desired (and/or alternatively predetermined) due to the process error or so on, the second cover portion 362b is disposed on the upper portion of the spacer 350, and thus, the height HC of the cover layer 360 that is disposed on the upper portion of the spacer 350 may be sufficiently protected and the spacer 350 may be reduced and/or prevented from being exposed to an outside. Thereby, a plasma induced damage (PID) that may be induced in a subsequent process using plasma may be reduced and/or minimized and problems due to a hydrogen penetration may be reduced and/or minimized. Accordingly, performance and/or reliability of the transistor 300 (e.g., the first transistor 400 having the high dielectric constant metal gate structure and/or the second transistor 500 of the high voltage transistor) may be enhanced.

On the other hand, in a comparative example in which an upper end of a spacer reaches a first surface of a capping layer in a vertical direction, when a cover layer is undesirably removed due to a process error or so on, a thickness of the cover layer that is disposed on an upper portion of the spacer is small or a partial portion of the spacer may be exposed to an outside. Thereby, a plasma induced damage may be induced in a subsequent process using plasma, or a hydrogen may penetrate into a transistor in a subsequent process and an electrical property of the transistor may be undesirably changed. For example, when a first insulation layer includes silicon oxide and has a large amount of hydrogen, the hydrogen included in the first insulation layer may penetrate into the transistor and the electrical property of the transistor may be undesirably changed. That is, a thickness or a height of the cover layer that is disposed on the upper portion of the spacer is closely related to the performance of the transistor. In the comparative example, the thickness or the height of the cover layer that is disposed on the upper portion of the spacer might not be sufficiently protected and the performance of the transistor may be deteriorated. This may be more likely to occur when the plurality of transistors have different heights, as described in the above.

That is, in some example embodiments, when the plurality of transistors 300 have different heights, the cover layer 360 may be undesirably removed in the removal process of the first interlayer insulation layer 282m. As in the above example, the first surface 3601 of the cover layer 360 that is included in the first conductivity type transistor 400a having the largest first height H1 may act as the stopping layer in the removal process. An area of the first surface 3601 of the cover layer 360 acting as the stopping layer may be small and it may be difficult to stop the removal process at the first surface 3601 of the cover layer 360. In some example embodiments, even when the plurality of transistors 300 have different heights and the cover layer 360 is undesirably removed, the deterioration of the transistor 300 may be effectively prevented, reduced, and/or minimized.

In some example embodiments, the first separation distance D1 may be greater than a thickness T1 of the second capping layer 316b. The thickness T1 of the second capping layer 316b may refer to a thickness of the side portion 316e, a thickness of the first upper portion 316f, a thickness of the second upper portion 316g, or a maximum thickness of the second capping layer 316b. When the first separation distance D1 is greater than the thickness T1 of the second capping layer 316b, the height HC of the cover layer 360 that is disposed on the upper portion of the spacer 350 may be greater than a desired (and/or alternatively predetermined) level. However, the example embodiments are not limited thereto. The first separation distance D1 may be the same as or less than the thickness T1 of the second capping layer 316b.

In some example embodiments, the first separation distance D1 may be greater than a thickness T2 of the cover layer 360. The thickness T2 of the cover layer 360 may refer to a thickness of the side cover portion 362, a thickness of the second upper cover portion 366, or a maximum thickness of the cover layer 360. When the first separation distance D1 is greater than the thickness T2 of the cover layer 360, he height HC of the cover layer 360 that is disposed on the upper portion of the spacer 350 may be greater than a desired (and/or alternatively predetermined) level. However, the example embodiments are not limited thereto. The first separation distance D1 may be the same as or less than the thickness T2 of the cover layer 360.

For example, the first separation distance D1 may be greater than a sum (T1+T2) of the thickness T1 of the second capping layer 316b and the thickness T2 of the cover layer 360. Thereby, the height HC of the cover layer 360 that is disposed on the upper portion of the spacer 350 may be relatively large. However, the example embodiments are not limited thereto. The first separation distance D1 may be the same as or less than the sum (T1+T2) of the thickness T1 of the second capping layer 316b and the thickness T2 of the cover layer 360.

In some example embodiments, the height HC of the cover layer 360 that is disposed on the upper portion of the spacer 350 may be greater than the first separation distance D1. The cover layer 360 that is disposed on the upper portion of the spacer 350 may include a portion that corresponds to the first separation distance D1 and extend to the first surface 3601 of the cover layer 360, and may have the height HC greater than the first separation distance D1.

In some example embodiments, the height HC of the cover layer 360 that is disposed on the upper portion of the spacer 350 may be greater than the thickness T1 of the second capping layer 316b. The height HC of the cover layer 360 that is disposed on the upper portion of the spacer 350 may be greater than the thickness T2 of the cover layer 360. The height HC of the cover layer 360 that is disposed on the upper portion of the spacer 350 may be greater than the sum (T1+T2) of the thickness T1 of the second capping layer 316b and the thickness T2 of the cover layer 360. However, the example embodiments are not limited thereto. The height HC of the cover layer 360 that is disposed on the upper portion of the spacer 350 may be the same as or less than the thickness T1 of the second capping layer 316b, the thickness T2 of the cover layer 360, or the sum (T1+T2) of the thickness T1 of the second capping layer 316b and the thickness T2 of the cover layer 360.

In some example embodiments, a ratio {D1/(T1+T3)} of the first separation distance D1 to the thickness of the capping layer 316 (e.g., a sum (T1+T3) of the thickness T1 of the first capping layer 316a and the thickness T3 of the second capping layer 316b) that is disposed on the gate electrode 314 may be in a range of 0.05 to 0.95 (e.g., 0.1 to 0.9). Thereby, the upper end 3501 of the spacer 350 may be stably disposed between the first surface 3161 of the capping layer 316 and the second surface 3162 of the capping layer 316.

For example, the first separation distance D1 may be the same or greater than the second separation distance D2. Thereby, the first separation distance D1 and the height HC of the cover layer 360 that is disposed on the upper portion of the spacer 350 may sufficiently protect the spacer 350. However, the example embodiments are not limited thereto. The first separation distance D1 may be less than the second separation distance D2.

According to some example embodiments, the upper end 3501 of the spacer 350 may be spaced apart from the first surface 3161 of the capping layer 316 by the first separation distance D1 in the side surface of the gate structure 310, and the second side portion S2 in which the cover layer 360 is disposed on the upper portion of the spacer 350 may be included. Accordingly, the height HC of the cover layer 360 that is disposed on the upper portion of the spacer 350 may sufficiently protect the spacer 350. Thereby, a damage and/or a property change of the transistor 300 that may be induced in a subsequent processes may be reduced and/or minimized, and performance and/or reliability of the transistor 300 may be enhanced. Particularly, in the circuit region 200 or the semiconductor chip 10 that includes the plurality of transistors 300 having different heights, performance and/or reliability of the transistor 300 may be enhanced.

In the description, it is described as an example that the semiconductor chip 10 includes the cell region 100 and the circuit region 200. The circuit region 200, a semiconductor device, a semiconductor die, a semiconductor apparatus, or so on that includes the plurality of transistors 300 may be referred to as the semiconductor chip.

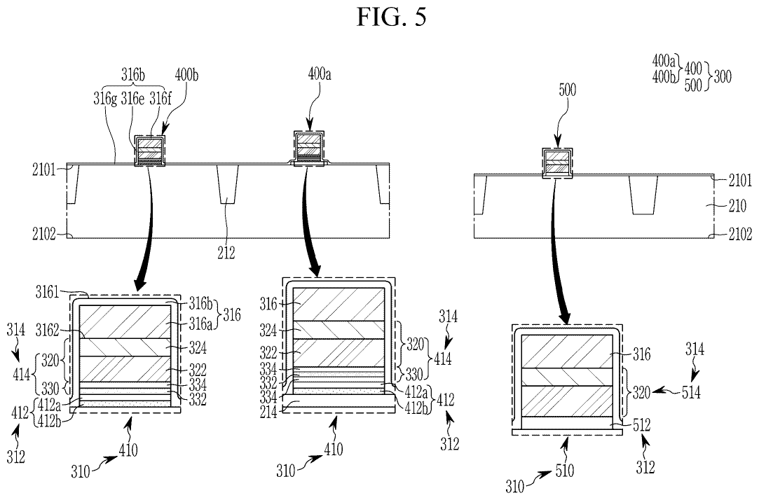

Hereinafter, examples of a manufacturing method of a semiconductor chip 10 having the above structure will be described in more detail with reference to FIGS. 5 to 13 together with FIG. 1 to FIG. 4. To the extent that an element is not described in detail below, it may be understood that the element is at least similar to a corresponding element that has been described elsewhere within the present disclosure. A portion which is not described in the above will be described in detail.

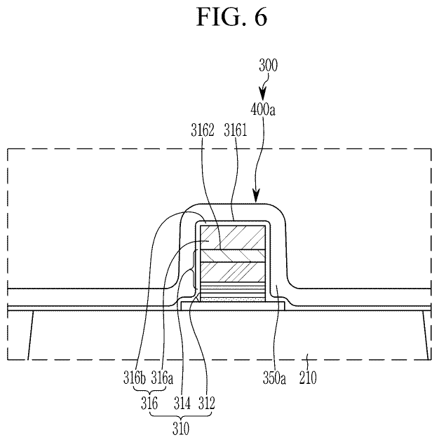

FIG. 5 to FIG. 10 are cross-sectional views that illustrate a manufacturing method of a semiconductor chip according to some example embodiments. FIG. 5 illustrates a portion corresponding to FIG. 3, and FIG. 6 to FIG. 10 illustrate a portion corresponding to FIG. 4. Hereinafter, a manufacturing method of a circuit region (e.g., a transistor) included in the semiconductor chip is mainly described. For a clear understanding, in FIG. 5 and FIG. 6, reference numerals are illustrated at portions where transistors 300 (e.g., a first conductivity type transistor 400a, a second conductivity type transistor 400b, and a second transistor 500) may be formed.

As illustrated in FIG. 5, gate structures 310 included in a plurality of transistors 300 may be formed. A device isolator 212 configured to separate, divide, or define active regions of the plurality of transistors 300 may be formed.

More particularly, a gate insulation layer 312, a gate electrode 314, and a first capping layer 316a may be formed on a first surface 2101 of a first substrate 210, and a patterning process of the gate insulation layer 312 and the gate electrode 314 may be performed by using the first capping layer 316a as a mask.

For example, a semiconductor layer 214, the gate insulation layer 312 (e.g., a first gate insulation layer 412 or a second gate insulation layer 512), and a buffer layer 330 may be formed on the first surface 2101 of the first substrate 210 to correspond to the plurality of transistors 300. In a region where the first conductivity type transistor 400a may be disposed, the semiconductor layer 214, the first gate insulation layer 412, and the buffer layer 330 may be disposed. In a region where the second conductivity type transistor 400b may be disposed, the first gate insulation layer 412 and the buffer layer 330 may be disposed. In a region where the second transistor 500 may be disposed, the second gate insulation layer 512 may be disposed. A formation order of the semiconductor layer 214, the first gate insulation layer 412, the second gate insulation layer 512, and the buffer layer 330 may be variously modified, and the example embodiments are not limited thereto. The semiconductor layer 214, the first gate insulation layer 412, the second gate insulation layer 512, or the buffer layer 330 may be formed by any of various processes (e.g., a deposition process).

A base electrode layer 320 may be formed on the semiconductor layer 214, the gate insulation layer 312 (e.g., the first gate insulation layer 412 or the second gate insulation layer 512), and the buffer layer 330. The base electrode layer 320 may be formed by any of various processes (e.g., a deposition process).

The first capping layer 316a may be formed on the base electrode layer 320. The first capping layer 316a may be formed by any of various processes (e.g., a deposition process), and a patterning process of the first capping layer 316a may be performed by any of various processes (e.g., a photolithography process).

Partial portion of the gate insulation layer 312 and the gate electrode 314 may be removed by using the first capping layer 316a as a mask layer. For the process of removing the gate insulation layer 312, and the gate electrode 314, any of various processes (e.g., a dry etching process, a wet etching process, or so on) may be used.

A second capping layer 316b may be formed on the gate insulation layer 312, the gate electrode 314, the first capping layer 316a, and the first substrate 210. The second capping layer 316b may include a side portion 316e that is disposed at a side surface of the gate structure 310, and may include a first upper portion 316f that is disposed at an upper surface of the gate structure 310, and a second upper portion 316g that is disposed on the first surface 2101 of the first substrate 210.

In some example embodiments, in a plurality of processes of forming the plurality of gate structures 310 included in the plurality of transistors 300, the device isolator 212 may be formed before or after one of the plurality of processes. An order of a process of forming the device isolator 212 may be variously modified. For the process of forming the device isolator 212, any of various processes may be used. For example, the device isolator 212 may be formed by forming a trench using an etching process at a side of the first surface 2101 of the first substrate 210 and then filling an insulating material to the trench.

Subsequently, as illustrated in FIG. 6, a preliminary spacer layer 350a may be formed to entirely cover an upper surface and a side surface of the gate structure 310, and the first substrate 210. For example, the preliminary spacer layer 350a may be formed on the first upper portion and the side portion of the second capping layer 316b that is disposed on the gate structure 310 and on the second upper portion of the second capping layer 316b that is disposed on the first substrate 210. The preliminary spacer layer 350a may be formed by any of various processes (e.g., a deposition process).

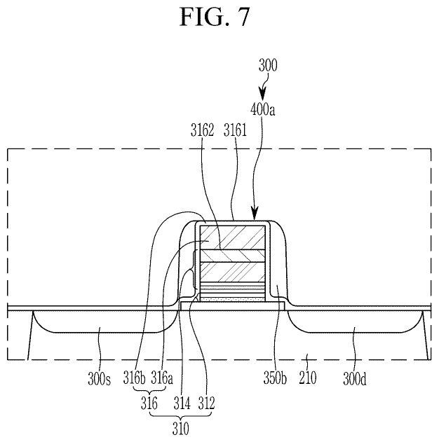

Subsequently, as illustrated in FIG. 7, a preliminary spacer 350b may be formed by patterning the preliminary spacer layer 350a (refer to FIG. 6), and source and drain regions 300s and 300d may be formed by using the capping layer 316 and the preliminary spacer 350b as a mask.

More particularly, by the patterning process of removing a portion of the preliminary spacer layer 350a on the first upper portion and the second upper portion of the second capping layer 316b, the preliminary spacer 350b may be formed on the side surface of the gate structure 310. The patterning process of the preliminary spacer layer 350a may be performed by any of various processes (e.g., a dry etching process, a wet etching process, or so on).

The preliminary spacer 350b may be formed to entirely cover the side surface of the gate structure 310. That is, in the side surface of the gate structure 310, the preliminary spacer 350b may extend from an upper surface of the gate structure 310 (e.g., a first surface 3161 of the capping layer 316) to a lower surface of the gate structure 310. Accordingly, an upper end of the preliminary spacer 350b in an outer side surface of the preliminary spacer 350b may reach the upper surface of the gate structure 310 (e.g., the first surface 3161 of the capping layer 316). The preliminary spacer 350b may have a width capable of forming the source and drain regions 300s and 300d of desired sizes. The source and drain regions 300s and 300d may be formed by any of various processes (e.g., an ion implantation process or so on).

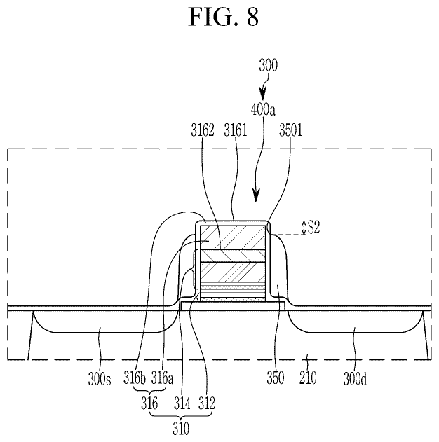

Subsequently, as illustrated in FIG. 8, a partial portion (more particularly, an upper portion) of the preliminary spacer 350b (refer to FIG. 7) may be removed. Thereby, a second side portion S2 may be formed at an upper portion of the spacer 350. The second side portion S2 may be disposed in a portion corresponding to a partial portion of the side surface of the gate structure 310 (e.g., a partial portion of the side surface of the capping layer 316). In the second side portion S2, the spacer 350 is not disposed. The spacer 350 may have a kind of a partial recess in the second side portion S2.

By the process of etching the partial portion of the preliminary spacer 350b, in a vertical direction that is perpendicular to the first substrate 210, an upper end 3501 of the spacer 350 may be disposed between a first surface 3161 and a second surface 3162 of the capping layer 316. That is, in the process of etching the partial portion of the preliminary spacer 350b, a partial portion of the preliminary spacer 350b from an upper end of the preliminary spacer 350b to the upper end 3501 of the spacer 350 may be etched.

The process of etching the partial portion of the preliminary spacer 350b may be performed by a wet etching process or a dry etching process. For example, when the partial portion of the preliminary spacer 350b may be etched by a dry etching process using a dry cleaning process or plasma, the upper portion of the preliminary spacer 350b may be removed without a damage of the other portion by using linearity or straightness of the dry etching process. For example, by using a chemical oxide removal (COR) process that is the dry cleaning process, process cost may be reduced. However, the example embodiments are not limited thereto. Various modifications are possible.

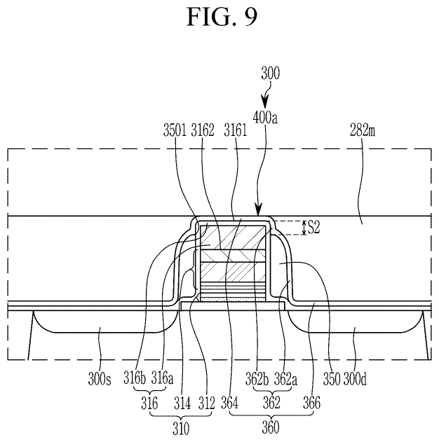

Subsequently, as illustrated in FIG. 9, a cover layer 360 and a first interlayer insulation layer 282m may be sequentially formed on the first substrate 210 to cover the gate structure 310 and the spacer 350, and a partial portion of the first interlayer insulation layer 282m may be removed by using the cover layer 360 as a stopping layer.

In some example embodiments, the cover layer 360 may include a side cover portion 362. The side cover portion 362 may include a first cover portion 362a that is disposed on the outer side surface of the spacer 350 and a second cover portion 362b that is disposed on the side surface of the gate structure 310. The cover layer 360 may include a first upper cover portion 364 and a second upper cover portion 366 that are disposed on the upper surface of the gate structure 310 and the first substrate 210, respectively. By entirely forming the cover layer 360 on the first substrate 210, a manufacturing process may be simplified. However, the example embodiments are not limited thereto. The cover layer 360 may be formed by any of various processes (e.g., a deposition process).

The removal process of removing the partial portion of the first interlayer insulation layer 282m by using the cover layer 360 as the stopping layer may be performed by any of various processes (e.g., a polishing process, as an example, a chemical mechanical polishing process). For example, when the polishing reaches the cover layer 360 of a first conductivity type transistor 400a that has the largest height (e.g., a first height) in the polishing process, the polishing process may be stopped.

Since the side cover portion 362 (e.g., the second cover portion 362b) may be disposed on the side surface of the gate structure 310 without the spacer 350, even if the polishing is performed more than desired (and/or alternatively predetermined) due to a process error, the side cover portion 362 may be stably disposed on the upper portion of the spacer 350. That is, by the second cover portion 362b of the side cover portion 362 that is disposed on the upper portion of the spacer 350, the side surface of the gate structure 310 may be stably covered and the spacer 350 may be reduced and/or prevented to be exposed to an outside. Particularly, the effects may increase in some example embodiments that includes the plurality of transistors 300 having various heights.

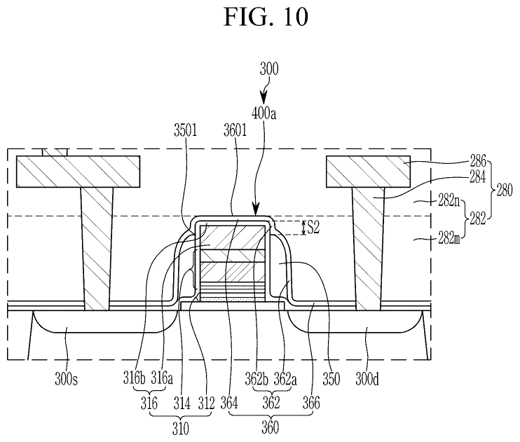

Subsequently, as illustrated in FIG. 10, a first wiring portion 280 may be formed by forming a second interlayer insulation layer 282n on the first interlayer insulation layer 282m and forming a contact via 284 and a wiring layer 286. Thereby, a circuit region or a semiconductor chip including the circuit portion may be formed.

According to some example embodiments, the source and drain regions 300s and 300d may be formed by using the preliminary spacer 350b, and the source and drain regions 300s and 300d may be stably formed. Since the spacer 350 is formed by removing the partial portion of the preliminary spacer 350b after the source and drain regions 300s and 300d are formed, the source and drain regions 300s and 300d may be stably formed and the spacer 350 of a wanted shape may be formed. Thereby, performance and/or reliability of the transistor 300 may be enhanced by a stable manufacturing process.

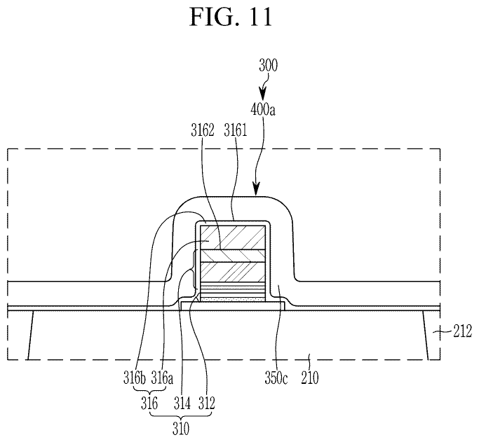

FIG. 11 to FIG. 13 are cross-sectional views that illustrate a manufacturing method of a semiconductor chip according to some example embodiments. FIG. 11 to FIG. 13 illustrate a portion corresponding to FIG. 4. Hereinafter, a manufacturing method of a circuit region (e.g., a transistor) included in the semiconductor chip is mainly described. For a clear understanding, in FIG. 11, reference numerals are illustrated at portions where transistors 300 may be formed.

As illustrated in FIG. 11, gate structures 310 included in a plurality of transistors 300, a device isolator 212, and a preliminary spacer layer 350c may be formed. Unless otherwise described the description with reference to FIG. 5 and FIG. 6 may be applied to the gate structures 310, the device isolator 212, and the preliminary spacer layer 350c.

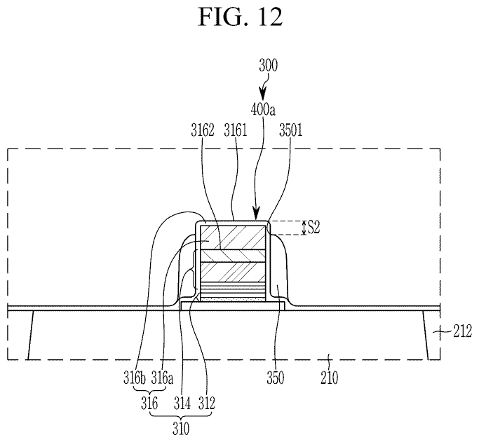

A preliminary spacer layer 350c illustrated in FIG. 11 may have a sufficient thickness capable of forming a spacer 350 (refer to FIG. 12) corresponding to source and drain regions 300s and 300d (refer to FIG. 12) of a wanted size. This may be because the preliminary spacer layer 350c may be etched in a relatively large amount in a patterning process of removing a partial portion of the preliminary spacer layer 350c to form a spacer 350 (refer to FIG. 12) so that an upper end 3501 (refer to FIG. 12) of the spacer 350 is disposed at a lower portion of an upper surface of the gate structure 310 (e.g., a first surface 3161 of a capping layer 316). For example, the preliminary spacer layer 350c illustrated in FIG. 11 may have a thickness greater than a thickness of the preliminary spacer layer 350a illustrate in FIG. 5.

Subsequently, as illustrated in FIG. 12, a spacer 350 may be formed by a patterning process of removing a partial portion of the preliminary spacer layer 350c (refer to FIG. 11). In the patterning process of the spacer 350, the spacer 350 may be etched so that the upper end of the spacer 350 is disposed at the lower portion of the upper surface of the gate structure 310 (e.g., the first surface 3161 of the capping layer 316). That is, in the patterning process of the spacer 350, a partial recess structure of the spacer 350 may be formed. Thereby, a process of forming a preliminary spacer 350b (refer to FIG. 7) may be omitted and a manufacturing process may be simplified.

The process of etching the partial portion of the preliminary spacer layer 350c may be performed by a wet etching process or a dry etching process. For example, when the partial portion of the preliminary spacer layer 350c may be etched by a dry etching process using plasma, the patterning process, and the process of forming the partial recess structure may be stably performed. However, the example embodiments are not limited thereto. Various modifications are possible.

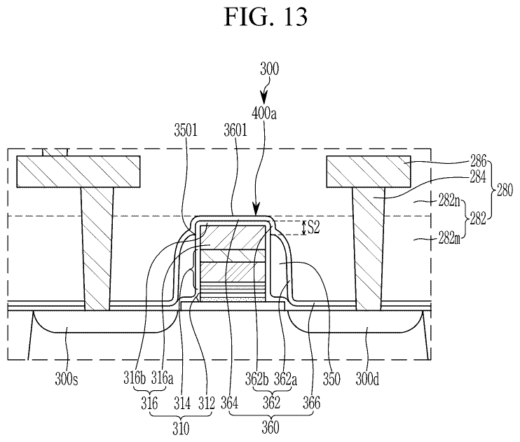

Subsequently, as illustrated in FIG. 13, source and drain regions 300s and 300d may be formed by using the capping layer 316 and the spacer 350 as a mask. The source and drain regions 300s and 300d may be formed by any of various processes (e.g., an ion implantation process, or so on).

Subsequently, a cover layer 360 and a first interlayer insulation layer 282m may be sequentially formed on the first substrate 210 to cover the gate structure 310 and the spacer 350, and a partial portion of the first interlayer insulation layer 282m may be removed by using the cover layer 360 as a stopping layer. The description with reference to FIG. 9 may be applied thereto.

Subsequently, a first wiring portion 280 may be formed by forming a second interlayer insulation layer 282n on the first interlayer insulation layer 282m and forming a contact via 284 and a wiring layer 286. Thereby, a circuit region or a semiconductor chip including the circuit portion may be formed.

According to some example embodiments, in the patterning process of the spacer 350, the partial recess structure of the spacer 350 may be formed. Thereby, a process of forming a preliminary spacer 350b (refer to FIG. 7) may be omitted and a manufacturing process may be simplified. Performance and reliability of the transistor 300 may be enhanced by a simple manufacturing process.

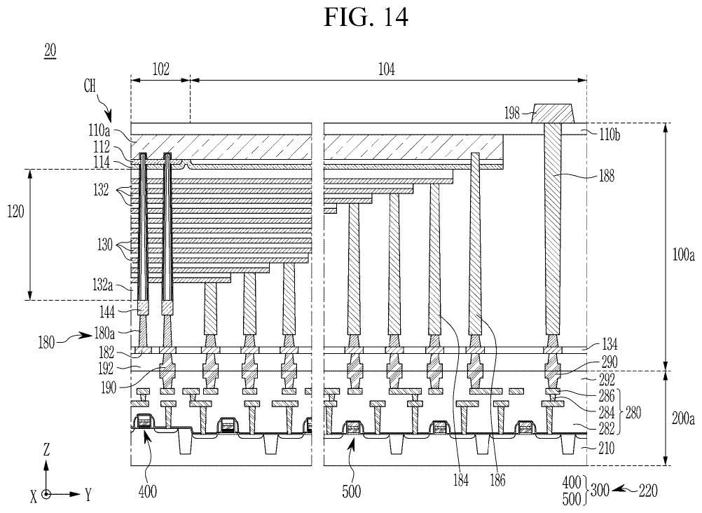

Hereinafter, a semiconductor chip 20 according to some example embodiments will be described in more detail with reference to FIG. 14. To the extent that an element is not described in detail below, it may be understood that the element is at least similar to a corresponding element that has been described elsewhere within the present disclosure. A portion which is not described in the above will be described in detail.

FIG. 14 is a cross-sectional view schematically illustrating a semiconductor chip 20 according to some example embodiments.

Referring to FIG. 14, a semiconductor chip 20 according to some example embodiments may have a chip-to-chip (C2C) structure bonded by a wafer bonding type. That is, a lower chip including a circuit region 200a including a peripheral circuit structure on a first substrate 210 may be manufactured, an upper chip including a memory cell structure on a second substrate 110a may be manufactured, and the lower chip and the upper chip may be bonded to each other to manufacture the semiconductor chip 20.

The circuit region 200a may include the first substrate 210, a circuit element 220, a first wiring portion 280, and a first bonding structure 290 electrically connected to the first wiring portion 280 at a surface facing the cell region 100a. A region other than the first bonding structure 290 at the surface facing the cell region 100a may be covered by a first bonding insulation layer 292.

The cell region 100a may include the second substrate 110a, a gate stacking structure 120, a channel structure CH, a second wiring portion 180, and a second bonding structure 190 electrically connected the second wiring portion 180 at a surface facing the circuit region 200a. A region other than the second bonding structure 190 may be covered by a second bonding insulation layer 192.

In some example embodiments, the second substrate 110a may be a semiconductor substrate including a semiconductor material. For example, the second substrate 110a may include a semiconductor layer including or formed of a single-crystallin or polycrystalline silicon, germanium, silicon-germanium, or so on. However, example embodiments are not limited thereto. In some example embodiments, the second substrate 110a may further include an insulation layer. That is, after the cell region 100a may be bonded to the circuit region 200a, a semiconductor substrate that was provided in the cell region 100a may be removed and an insulation layer may be formed.

In some example embodiments, the gate stacking structure 120 may be sequentially stacked on a lower portion of the second substrate 110a in the drawing, and may have a structure in which a gate stacking structure 120 illustrated in FIG. 1 is disposed in a vertically inverted manner. The channel structure CH passing through or penetrating the gate stacking structure 120 may have a structure in which a channel structure CH illustrated in FIG. 2 is disposed in a vertically inverted manner. Accordingly, in a cross-sectional view, the channel structure CH may have an inclined side surface such that a width of the channel structure CH decreases from the circuit region 200a toward the second substrate 110a. A channel pad 144 and the second wiring portion 180 on the gate stacking structure 120 may be adjacent to the circuit region 200a.

For example, the first bonding structure 290 and/or the second bonding structure 190 may include aluminum, copper, tungsten, or an alloy including the same. For example, the first and second bonding structures 290 and 190 may include or be formed of copper so that the cell region 100a and the circuit region 200a may be bonded (e.g., directly bonded) to each other by copper-to-copper bonding. However, example embodiments are not limited thereto.

In FIG. 14, it is illustrated as an example that the gate stacking structure 120 includes one gate stacking structure. In some embodiment, the gate stacking structure 120 may include a plurality of gate stacking structures. Unless otherwise described, the description of the gate stacking structure 120 and the channel structure CH with reference to FIG. 1 to FIG. 4 may be applied to the gate stacking structure 120 and the channel structure CH. In FIG. 14, it is illustrated as an example that an electrical connection structure of the channel structure CH with horizontal conductive layers 112 and 114 and/or the second substrate 110a is the same as an electrical connection structure of the channel structure CH with the horizontal conductive layers 112 and 114 and/or the second substrate 110 in FIG. 1. The example embodiments are not limited thereto, and the electrical connection structure of the channel structure CH with the horizontal conductive layers 112 and 114 and/or the second substrate 110a may be variously modified.

The semiconductor chip 20 according to some example embodiments may include an input/output pad, and a through plug or an input/output connection wiring electrically connected to the input/output pad. The through plug or input/output connection wiring may be electrically connected to a part of the second bonding structure 190. For example, the input/output pad may be on an insulation layer 110b covering an outer surface of the second substrate 110a. In some example embodiments, an additional input/output pad electrically connected to the circuit region 200a may be provided.

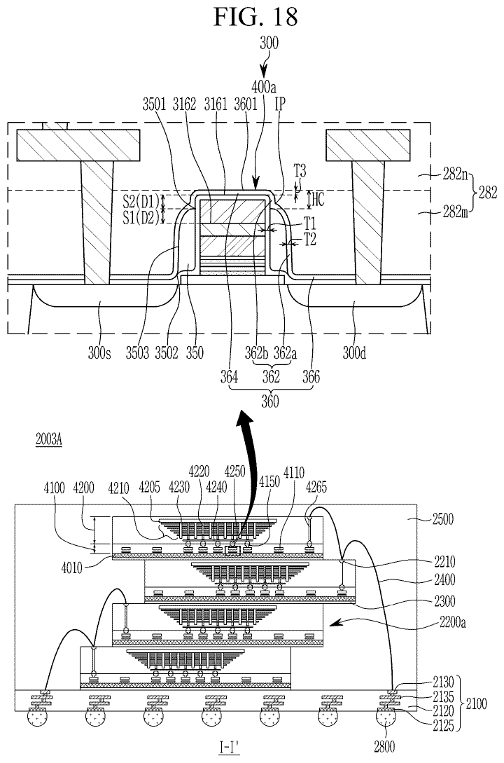

For example, the circuit region 200a and the cell region 100a may be portions corresponding to a first structure 1100F and a second structure 1100S of a semiconductor device 1100 included in an electronic system 1000 illustrated in FIG. 15, respectively. For example, the circuit region 200a and the cell region 100a may be regions including a first structure 4100 and a second structure 4200 of a semiconductor chip 2200a illustrated in FIG. 18, respectively.

Hereinafter, an example of an electronic system that includes a semiconductor chip described in the above will be described in detail.

FIG. 15 schematically illustrates an electronic system that includes a semiconductor device or a semiconductor chip according to some example embodiments.

Referring to FIG. 15, an electronic system 1000 according to some example embodiments may include a semiconductor device 1100 and a controller 1200 that is electrically connected to the semiconductor device 1100. The semiconductor device 1100 may be referred to as a semiconductor chip, a semiconductor die, or a semiconductor apparatus. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 14. The semiconductor device 1100 may include a first structure 1100F and a second structure 1100S that is disposed on the first structure 1100F. In some example embodiments, the first structure 1100F may be next to the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to some example embodiments.

In some example embodiments, the lower transistor LT1 or LT2 may include a ground selection transistor, and the upper transistor UT1 or UT2 may include a string selection transistor. The first and second gate lower lines LL1 and LL2 may be gate electrode layers of the lower transistors LT1 and LT2, respectively. The word line WL may be a gate electrode layer of the memory cell transistor MCT, and the gate upper lines UL1 and UL2 may be gate electrode layers of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some example embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to desired (and/or alternatively predetermined) firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or so on may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

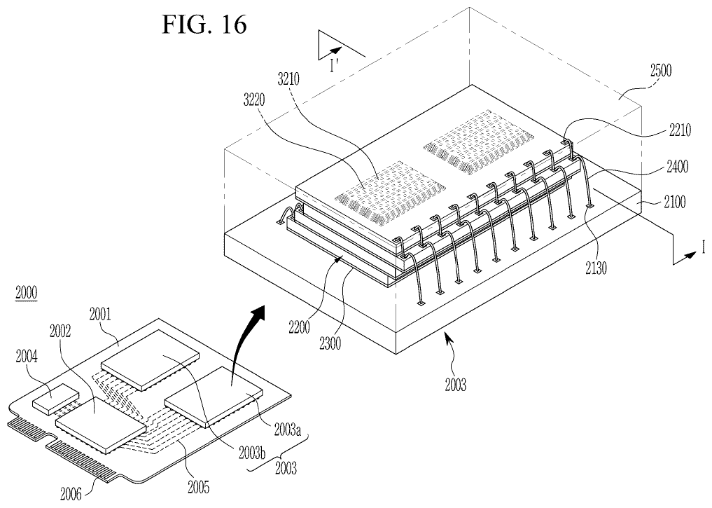

FIG. 16 is a perspective view that schematically illustrates an electronic system including a semiconductor device or a semiconductor chip according to some example embodiments.

Referring to FIG. 16, an electronic system 2000 according to some example embodiments may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In some example embodiments, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In some example embodiments, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may a semiconductor package including a plurality of semiconductor chips 2200. Each of the first and second semiconductor packages 2003a and 2003b may include a package substrate 2100, the semiconductor chip 2200 that is disposed on the package substrate 2100, an adhesive layer 2300 at a lower surface of each semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 15. Each semiconductor chip 2200 may include a gate stacking structure 3210 and a channel structure 3220. The semiconductor chip 2200 may include a semiconductor chip described with reference to FIG. 1 to FIG. 14.

In some example embodiments, the connection structure 2400 may be a bonding wire that electrically connects the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to the package upper pad 2130 of the package substrate 2100. According to some example embodiments, in each of the first and second semiconductor packages 2003a and 2003b, the semiconductor chips 2200 may be electrically connected to each other by a connection structure that includes a through silicon via (TSV) instead of the connection structure 2400 of the bonding wire type. However, example embodiments are not limited thereto.

In some example embodiments, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring of the interposer substrate.

FIG. 17 and FIG. 18 are cross-sectional views schematically illustrating semiconductor packages according to embodiments, respectively. FIG. 17 and FIG. 18 respectively illustrate embodiments of the semiconductor package 2003 of FIG. 16, and conceptually illustrate a region obtained by cutting the semiconductor package 2003 of FIG. 16 along a line I-I′.

Referring to FIG. 17, in a semiconductor package 2003, a package substrate 2100 may be a printed circuit board. The package substrate 2100 may include a package substrate body portion 2120, a package upper pad 2130 that is disposed at an upper surface of the package substrate body portion 2120, a package lower pad 2125 that is disposed at a lower surface of the package substrate body portion 2120 or is exposed through the lower surface of the package substrate body portion 2120, and an internal wiring 2135 that electrically connects the package upper pad 2130 and the package lower pad 2125 inside the package substrate body portion 2120. The package upper pad 2130 may be electrically connected to the connection structure 2400. The package lower pad 2125 may be connected to a wiring pattern 2005 of a main substrate 2001 of an electronic system 2000, as illustrated in FIG. 16, through a conductive connection portion 2600.

The semiconductor chip 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 on the common source line 3205, a channel structure 3220 and a separation structure 3280 passing through the gate stacking structure 3210, a bit line 3240 electrically connected to the channel structure 3220, and a gate connection wiring electrically connected to a word line WL (refer to FIG. 17) of the gate stacking structure 3210.

In the semiconductor chip 2200 according to some example embodiments, a height of a cover layer that is disposed on an upper portion of a spacer may sufficiently protect the semiconductor device (e.g., a transistor), thereby enhancing the performance and/or reliability of the semiconductor device. Particularly, in a case that includes a plurality of semiconductor devices having different heights, performance and/or reliability of the semiconductor device may be enhanced.

Each of the semiconductor chips 2200 may include a through wiring 3245 that is electrically connected to a peripheral wiring 3110 of the first structure 3100 and extends into the second structure 3200. The through wiring 3245 may pass through the gate stacking structure 3210, and may be further provided at an outside of the gate stacking structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In some example embodiments, in the semiconductor package 2003, a plurality of semiconductor chips 2200 may be electrically connected to each other by a connection structure 2400 having a bonding wire type. In some example embodiments, the plurality of semiconductor chips 2200 or a plurality of portions constituting the plurality of semiconductor chips 2200 may be electrically connected by a connection structure including a through silicon via (TSV).

Referring to FIG. 18, in a semiconductor package 2003A, each semiconductor chip 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region that includes a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 that pass through the gate stacking structure 4210, and a second bonding structures 4250 that are electrically connected to the channel structure 4220 and a word line WL (refer to FIG. 12) of the gate stacking structure 4210. For example, the second bonding structure 4250 may be electrically connected to the channel structure 4220 and the word line WL through a bit line 4240 that is electrically connected to the channel structure 4220 and a gate connection wiring that is electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu). However, example embodiments are not limited thereto.

In the semiconductor chip 2200a according to some example embodiments, a height of a cover layer on an upper portion of a spacer may sufficiently protect the semiconductor device (e.g., a transistor), thereby enhancing the performance and/or reliability of the semiconductor device. Particularly, in a case that includes a plurality of semiconductor devices having different heights, performance and reliability of the semiconductor device may be enhanced.

Each of the semiconductor chips 2200a may further include an input/output pad 2210 and an input/output connection wiring 4265 that is disposed at a lower portion of the input/output pad 2210. The input/output connection wiring 4265 may be electrically connected to a part of the second bonding structures 4250.

In some example embodiments, in the semiconductor package 2003A, a plurality of semiconductor chips 2200a may be electrically connected to each other by a connection structure 2400 having a bonding wire type. In some example embodiments, a plurality of semiconductor chips 2200a may be electrically connected to each other by a connection structure including a through silicon via (TSV).

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some examples have been described in connection with what is presently considered to be some practical embodiments, it is to be understood that the disclosure is not limited to the disclosed embodiments, and that that the disclosure is intended to cover various modifications and equivalent arrangements included within the spirit and scope of the appended claims.

What is claimed is:

1. A semiconductor chip, comprising:
a substrate;
a plurality of transistors on the substrate;
each of the plurality of transistors including a gate structure and a spacer on a side surface of the gate structure;
the gate structure including
a gate insulation layer,
a gate electrode, and
a capping layer;
at least a portion of the capping layer is on the gate electrode, and the capping layer includes an insulating material; and
a cover layer includes a material different from a material of the spacer, and the cover layer covers the gate structure and the spacer,
wherein the capping layer includes
a first surface opposite to the gate electrode, and
a second surface adjacent to the gate electrode, and
an upper end of the spacer adjacent to the side surface of the gate structure is between the first surface of the capping layer and the second surface of the capping layer in a vertical direction, the vertical direction being a direction perpendicular to an upper surface of the substrate.

2. The semiconductor chip of claim 1, wherein at least one transistor of the plurality of transistors has a height in the vertical direction different from a height of at least one other transistor of the plurality of transistors in the vertical direction.

3. The semiconductor chip of claim 1, wherein
a side surface of the capping layer includes a first side portion and a second side portion,
the spacer and the cover layer are on the first side portion, and
the second side portion is on the first side portion in the vertical direction and the cover layer is on the second side portion.

4. The semiconductor chip of claim 1, wherein
the cover layer includes a side cover portion on the side surface of the gate structure and an outer side surface of the spacer, and
the side cover portion includes a first cover portion on the spacer and a second cover portion on at least a portion of a side surface of the capping layer without the spacer therebetween.

5. The semiconductor chip of claim 1, wherein
at least one of a height of the cover layer on an upper portion of the spacer in the vertical direction and a first separation distance between the upper end of the spacer and the first surface of the capping layer in a vertical direction is greater than a thickness of the cover layer.

6. The semiconductor chip of claim 1, wherein
the upper end of the spacer adjacent to the side surface of the gate structure is spaced apart from the first surface of the capping layer in a vertical direction by a first separation distance,
the upper end of the spacer is spaced apart from the second surface of the capping layer in a vertical direction by a second separation distance, and
the first separation distance is a same distance as the second separation distance or greater than the second separation distance.

7. The semiconductor chip of claim 1, wherein
an outer side surface of the spacer has a convex shape,
the cover layer includes a side cover portion on the side surface of the gate structure and the outer side surface of the spacer, and
the side cover portion has an inflection point or has a shape opposite to the convex shape of the spacer.

8. The semiconductor chip of claim 1, wherein
the plurality of transistors include a first transistor and a second transistor,
the second transistor has a height less than a height of the first transistor, and
the upper end of the spacer of the first transistor is between the first surface of the capping layer and the second surface of the capping layer.

9. The semiconductor chip of claim 8, wherein the upper end of the spacer of the second transistor is between the first surface of the capping layer and the second surface of the capping layer.

10. The semiconductor chip of claim 1, wherein the spacer includes silicon oxide, and
the cover layer includes silicon nitride.

11. The semiconductor chip of claim 1, wherein
each of the plurality of transistors further includes
a first transistor including a first gate structure and the spacer on a side surface of the first gate structure,
the first gate structure including
a first gate insulation layer,
a first gate electrode, and
the capping layer,
a second transistor including
a second gate structure and the spacer on a side surface of the second gate structure,
the second gate structure including
a second gate insulation layer,
a second gate electrode, and
the capping layer, and
wherein a stacking structure of the first transistor is different from a stacking structure of the second transistor, and
a height of the first transistor is different from a height of the second transistor.

12. The semiconductor chip of claim 11, wherein
the first gate insulation layer and the second gate insulation layer include at least one of a different material, a different stacking structure, and a different thickness, or
the first gate electrode and the second gate electrode include at least one of a different material, a different stacking structure, and a different thickness, or
a semiconductor layer is between the substrate and the first gate insulation layer and the semiconductor layer is not between the substrate and the second gate insulation layer.

13. The semiconductor chip of claim 11, wherein
the first gate insulation layer includes a high dielectric constant insulation layer that has a dielectric constant higher than a dielectric constant of silicon oxide, and
the second gate insulation layer includes silicon oxide.

14. The semiconductor chip of claim 11, wherein
the first gate electrode includes a base electrode layer and a buffer layer,
a thickness of the buffer layer is less than a thickness of the base electrode layer, and
the second gate electrode includes the base electrode layer.

15. The semiconductor chip of claim 11, wherein
the first transistor has a high dielectric constant metal gate (HKMG) structure, and
the second transistor has an operating voltage higher than an operating voltage of the first transistor.

16. The semiconductor chip of claim 11, wherein
the first transistor includes a first conductivity type transistor and a second conductivity type transistor having different conductivity types,
the second gate electrode of the first conductivity type transistor and the second gate electrode of second conductivity type transistor include at least one of a different materials, a different stacking structures, and a thickness, and
a semiconductor layer is between the substrate and the first gate insulation layer of the first conductivity type transistor and the semiconductor layer is not between the substrate and the first gate insulation layer of the second conductivity type transistor.

17. The semiconductor chip of claim 1, wherein
the semiconductor chip is a flash memory device that includes a circuit region and a cell region,
the cell region is on the circuit region and includes a memory cell structure, and
the circuit region includes the substrate, the plurality of transistors, and the cover layer.

18. A semiconductor device, comprising:
a gate structure on a substrate;
the gate structure including
a gate insulation layer,
a gate electrode, and
a capping layer;
at least a portion of the capping layer is on the gate electrode, and the capping layer includes an insulating material;
a spacer on a side surface of the gate structure; and
a cover layer that includes a material different from a material of the spacer, and the cover layer covers the gate structure and the spacer,
wherein the capping layer includes
a first surface opposite to the gate electrode, and
a second surface adjacent to the gate electrode, and
an upper end of the spacer adjacent to the side surface of the gate structure is between the first surface of the capping layer and the second surface of the capping layer in a vertical direction, the vertical direction being a direction perpendicular to an upper surface of the substrate.

19. The semiconductor device of claim 18, wherein
a side surface of the capping layer includes a first side portion and a second side portion,
the spacer and the cover layer are on the first side portion, and
the second side portion is on the first side portion in the vertical direction and the cover layer is on the second side portion; or
the cover layer includes a side cover portion on the side surface of the gate structure and an outer side surface of the spacer, and
the side cover portion includes a first cover portion on the spacer and a second cover portion on at least a portion of a side surface of the capping layer without the spacer therebetween.

20. An electronic system, comprising:
a main substrate;
a semiconductor chip on the main substrate; and
a controller electrically connected the semiconductor chip on the main substrate,
wherein the semiconductor chip includes:
a substrate;
a plurality of transistors on the substrate;
each of the plurality of transistors including a gate structure and a spacer on a side surface of the gate structure;
the gate structure including
a gate insulation layer,
a gate electrode, and
a capping layer;
at least a portion of the capping layer is on the gate electrode, and the capping layer includes an insulating material; and
a cover layer including a material different from a material of the spacer and covers the gate structure and the spacer,
wherein the capping layer includes
a first surface opposite to the gate electrode, and
a second surface adjacent to the gate electrode, and
an upper end of the spacer adjacent to the side surface of the gate structure is between the first surface of the capping layer and the second surface of the capping layer in a vertical direction, the vertical direction being a direction perpendicular to an upper surface of the substrate.
